(19) United States
(12) Patent Application Publication
(10) Pub. No.: US 2014/0299272 A1
(43) Pub. Date: Oct. 9, 2014

(54) PLASMA GENERATION DEVICE AND PLASMA PROCESSING APPARATUS

(71) Applicant: TOKYO ELECTRON LIMITED, Tokyo (JP)

(72) Inventors: Akihiro TSUJI, Tsukuba-shi (JP); Song yun KANG, Tokyo (JP)

(21) Appl. No.: 14/307,741

(22) Filed: Jun. 18, 2014

Related U.S. Application Data
(63) Continuation of application No. PCT/JP2012/083181, filed on Dec. 17, 2012.

(30) Foreign Application Priority Data
Dec. 19, 2011 (JP) 2011-276965
Dec. 20, 2011 (JP) 2011-278436
Dec. 26, 2011 (JP) 2011-283132

(51) Int. Cl. H01J 37/32

(52) U.S. Cl. CPC H01J 37/32201
USPC 156/345.36

(57) ABSTRACT

There is provided a plasma generation device, comprising: a waveguide configured to propagate a microwave; a plasma generation vessel connected to the waveguide; and a dielectric window interposed between the waveguide and the plasma generation vessel to introduce the microwave propagated by the waveguide into the plasma generation vessel. The plasma generation vessel is sphere-shaped and is disposed adjacent to a processing vessel configured to accommodate a substrate, and an interior of the plasma generation vessel is in communication with an interior of the processing vessel.

### CROSS-REFERENCE TO RELATED APPLICATION

This application is a Continuation application of PCT International Application No. PCT/JP2012/083181, filed Dec. 17, 2012, which claimed the benefit of Japanese Patent Application Nos. 2011-276965, filed on Dec. 19, 2011; 2011-278436, filed on Dec. 20, 2011; and 2011-283132, filed on Dec. 26, 2011, the entire contents of which are incorporated by reference herein.

### TECHNICAL FIELD

The present disclosure relates to a plasma generation device and a plasma processing apparatus for generating plasma using a microwave.

### BACKGROUND

In a conventional technology, a large number of plasma processing apparatuses, in which plasma is generated from a processing gas and substrates are processed by the plasma, have been used. For example, a parallel flat plate-type plasma processing apparatus, in which a high frequency electric field is generated by supplying high frequency power to a pair of parallel flat plate-shaped electrodes, electrons accelerated by the electric field and a processing gas cause various reaction to generate plasma, and plasma processing is performed on substrates using the plasma, has been generally used. In addition, a plasma processing apparatus using a microwave instead of a high frequency wave has also been used.

FIG. 31 is a sectional view schematically showing a configuration of a plasma processing apparatus using a microwave.

In FIG. 31, a plasma processing apparatus 450 includes a vacuum chamber 452 having an opening 451 for introducing a microwave at the upper center thereof, a substrate mounting table 453 disposed inside the vacuum chamber 452 to be mounted with a substrate S, a waveguide 454 through which the microwave is introduced into the opening 451, and a dielectric window 455 through which the microwave is introduced from the waveguide 454 into the vacuum chamber 452.

In the plasma processing apparatus 450, plasma is generated by the microwave from a processing gas introduced into the vacuum chamber 452, and a diamond film, for example, is grown on the substrate S mounted on the substrate mounting table 453 by radicals in the plasma (for example, see Patent Document 1).

When an electron density of the plasma is increased within the vacuum chamber 452, the plasma blocks the microwave that has been transmitted through the dielectric window 455. In addition, in non-uniform plasma having high density, resonance absorption occurs at a position where an electron plasma (angular) frequency and a microwave frequency coincide with each other. As a result, the plasma is actively generated in the vicinity of the dielectric window 455. If the plasma is generated under conditions of relatively high pressure, a temperature of the processing gas becomes extremely high. Accordingly, in some cases, the dielectric window 455 may be damaged by heat and the desired plasma may not be generated around the substrate S that is an object to be processed.

### SUMMARY

The present disclosure provides a plasma generation device and a plasma processing apparatus, which make it possible to prevent a dielectric window, through which a microwave is introduced, from being damaged and also to generate plasma in a desired region around a substrate.

According to a first aspect of the present disclosure, there is provided a plasma generation device, which includes: a waveguide configured to propagate a microwave; a plasma generation vessel connected to the waveguide; and a dielectric window interposed between the waveguide and the plasma generation vessel to introduce the microwave propagated by the waveguide into the plasma generation vessel.

According to a second aspect of the present disclosure, there is provided a plasma processing apparatus, which includes: a waveguide configured to propagate a microwave; a plasma generation vessel connected to the waveguide; a mounting table disposed in the plasma generation vessel and configured to be mounted with a substrate; and a dielectric window interposed between the waveguide and the plasma generation vessel to introduce the microwave propagated by the waveguide into the plasma generation vessel, wherein the plasma generation vessel has a central axis and has a shape symmetric with respect to the central axis.

According to a third aspect of the present disclosure, there is provided a plasma processing apparatus, which includes: a processing vessel configured to accommodate a substrate therein; and a plasma generation device disposed adjacent to the processing vessel, wherein the plasma generation device includes a waveguide configured to propagate a microwave, a plasma generation vessel connected to the waveguide, and a dielectric window interposed between the waveguide and the plasma generation vessel to introduce the microwave propagated by the waveguide into the plasma generation vessel, wherein an interior of the plasma generation vessel is in communication with an interior of the processing vessel.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view schematically showing a configuration of a plasma processing apparatus having a plasma generation device according to a first embodiment of the present disclosure.

FIG. 2A is a sectional view of a local part in the plasma processing apparatus of FIG. 1, showing a cross section of a waveguide.

FIG. 2B is a sectional view of a local part in the plasma processing apparatus of FIG. 1, showing a cross section of a microwave introduction passage defined between a cylindrical vessel and a cylindrical member.

FIG. 3A is a view schematically showing a configuration of a first modified example of the plasma generation unit in FIG. 1.

FIG. 3B is a view schematically showing a configuration of a second modified example of the plasma generation unit in FIG. 1.

FIG. 3C is a view schematically showing a configuration of a third modified example of the plasma generation unit in FIG. 1.

FIG. 3D is a view schematically showing a configuration of a fourth modified example of the plasma generation unit in FIG. 1.

FIG. 4A is a view schematically showing a configuration of a modified example of the plasma generation unit in FIG. 1, showing a fifth modified example.

FIG. 4B is a view schematically showing a configuration of a modified example of the plasma generation unit in FIG. 1, showing a sixth modified example.

FIG. 5A is a view showing a result of calculating an electric field intensity distribution when a radius of a plasma generation space in FIG. 1 is changed, where the plasma generation space has a radius of 5.5 cm.

FIG. 5B is a view showing a result of calculating an electric field intensity distribution when a radius of the plasma generation space in FIG. 1 is changed, where the plasma generation space has a radius of 8 cm.

FIG. 6A is a view showing a result of calculating an electric field intensity distribution when the plasma generation space in FIG. 1 is in communication with an interior of a processing chamber, where a stage is not installed.

FIG. 6B is a view showing a result of calculating an electric field intensity distribution when the plasma generation space in FIG. 1 is in communication with the interior of the processing chamber, where the distance from a stage to an upper inner surface of the processing chamber is set to 2 cm.

FIG. 6C is a view showing a result of calculating an electric field intensity distribution when the plasma generation space in FIG. 1 is in communication with the interior of the processing chamber, where the distance from the stage to the upper inner surface of the processing chamber is set to 1.5 cm.

FIG. 7 is a sectional view schematically showing a configuration of a plasma processing apparatus having a plasma generation device according to a second embodiment of the present disclosure.

FIG. 8A is a sectional view of a local part in the plasma processing apparatus of FIG. 7, showing a cross section of a dielectric window provided between a cylindrical vessel and a cylindrical member.

FIG. 8B is a sectional view of a local part in the plasma processing apparatus of FIG. 7, showing a cross section of a waveguide.

FIG. 9A is a view schematically showing a configuration of a modified example of the plasma processing apparatus in FIG. 7, showing a first modified example.

FIG. 9B is a view schematically showing a configuration of a modified example of the plasma processing apparatus in FIG. 7, showing a second modified example.

FIG. 9C is a view schematically showing a configuration of a modified example of the plasma processing apparatus in FIG. 7, showing a third modified example.

FIG. 10A is a view schematically showing a configuration of another modified example of the plasma processing apparatus in FIG. 7, showing a fourth modified example.

FIG. 10B is a view schematically showing a configuration of another modified example of the plasma processing apparatus in FIG. 7, showing a fifth modified example.

FIG. 11 is a sectional view schematically showing a configuration of a plasma processing apparatus having a plasma generation device according to a third embodiment of the present disclosure.

FIG. 12A is a view schematically showing a configuration of a modified example of the plasma processing apparatus in FIG. 11, showing a first modified example.

FIG. 12B is a view schematically showing a configuration of a modified example of the plasma processing apparatus in FIG. 11, showing a second modified example.

FIG. 12C is a view schematically showing a configuration of a modified example of the plasma processing apparatus in FIG. 11, showing a third modified example.

FIG. 13 is a view conceptually showing a configuration of the plasma generation device in the plasma processing apparatus of FIG. 11, showing a basic structure of the plasma generation device provided in a specific example.

FIG. 14A is a view showing a result of calculating an electric field intensity distribution when an inner radius of a plasma generation space in FIG. 13 is changed, where the plasma generation space has an outer radius of 10 cm and an inner radius of 4 cm.

FIG. 14B is a view showing a result of calculating an electric field intensity distribution when an inner radius of the plasma generation space in FIG. 13 is changed, where the plasma generation space has an outer radius of 10 cm and an inner radius of 8 cm.

FIG. 15A is a view showing a result of calculating an electric field intensity distribution when the plasma generation space and the processing chamber are integrated as shown in FIG. 11.

FIG. 15B is a view showing a result of calculating an electric field intensity distribution when the plasma generation space and the processing chamber are integrated, where a concave portion having a depth of 2 cm is provided in a stage shown in FIG. 11 and a substrate is disposed over the concave portion.

FIG. 15C is a view showing a result of calculating an electric field intensity distribution when the plasma generation space and the processing chamber are integrated, where a concave portion having a depth of 3 cm is provided in the stage shown in FIG. 11 and a substrate is disposed over the concave portion.

FIG. 16A is a view showing a result of calculating an electric field intensity distribution when the plasma generation space and the processing chamber are connected as shown in FIG. 7.

FIG. 16B is a view showing a result of calculating an electric field intensity distribution when the plasma generation space and the processing chamber are connected, where a gap from an upper end of the chamber to a stage surface is set to be 2.5 cm in FIG. 7.

FIG. 16C is a view showing a result of calculating an electric field intensity distribution when the plasma generation space and the processing chamber are connected, where the gap from the upper end of the chamber to a stage surface is set to be 1.5 cm in FIG. 7.

FIG. 17 is a sectional view schematically showing a configuration of a plasma processing apparatus according to a fourth embodiment of the present disclosure.

FIG. 18A is a sectional view of a local part in the plasma processing apparatus of FIG. 17, showing a cross section of a microwave introduction passage defined between a processing chamber and a stage.

FIG. 18B is a sectional view of a local part in the plasma processing apparatus of FIG. 17, showing a cross section of a waveguide.

FIG. 19A is a view schematically showing a configuration of a modified example of the plasma processing apparatus in FIG. 17, showing a first modified example.

FIG. 19B is a view schematically showing a configuration of a modified example of the plasma processing apparatus in FIG. 17, showing a second modified example.

FIG. 20A is a view schematically showing a configuration of a modified example of the plasma processing apparatus in FIG. 17, showing a third modified example.

FIG. 20B is a view schematically showing a configuration of a modified example of the plasma processing apparatus in FIG. 17, showing a fourth modified example.

FIG. 20C is a view schematically showing a configuration of a modified example of the plasma processing apparatus in FIG. 17, showing a fifth modified example.

FIG. 21 is a view schematically showing a configuration of a sixth modified example of the plasma processing apparatus in FIG. 17.

FIG. 22 is a sectional view schematically showing a configuration of a plasma processing apparatus according to a fifth embodiment of the present disclosure.

FIG. 23 is a view schematically showing a configuration of a first modified example of the plasma processing apparatus in FIG. 22.

FIG. 24A is a view schematically showing a configuration of a modified example of the plasma processing apparatus in FIG. 22, showing a second modified example.

FIG. 24B is a view schematically showing a configuration of a modified example of the plasma processing apparatus in FIG. 22, showing a third modified example.

FIG. 25A is a view schematically showing a configuration of a modified example of the plasma processing apparatus in FIG. 17, showing a seventh modified example.

FIG. 25B is a view schematically showing a configuration of a modified example of the plasma processing apparatus in FIG. 17, showing an eighth modified example.

FIG. 26A is a view showing a result of calculating an electric field intensity distribution when the height of a lift table from a substrate mounting surface is changed in the plasma processing apparatus of FIG. 19A, where the height of the lift table from the substrate mounting surface is set to 0 cm.

FIG. 26B is a view showing a result of calculating an electric field intensity distribution when the height of the lift table from the substrate mounting surface is changed in the plasma processing apparatus of FIG. 19A, where the height of the lift table from the substrate mounting surface is set to 2 cm.

FIG. 26C is a view showing a result of calculating an electric field intensity distribution when the height of the lift table from the substrate mounting surface is changed in the plasma processing apparatus of FIG. 19A, where the height of the lift table from the substrate mounting surface is set to 3 cm.

FIG. 27A is a view showing a result of calculating an electric field intensity distribution when the length of a stub is changed in the plasma processing apparatus of FIG. 20A, where the length of the stub is set to 1 cm.

FIG. 27B is a view showing a result of calculating an electric field intensity distribution when the length of the stub is changed in the plasma processing apparatus of FIG. 20A, where the length of the stub is set to 2 cm.

FIG. 27C is a view showing a result of calculating an electric field intensity distribution when the length of the stub is changed in the plasma processing apparatus of FIG. 20A, where the length of the stub is set to 3 cm.

FIG. 28A is a view showing a result of calculating an electric field intensity distribution when the distance between a facing surface and a substrate mounting surface is changed in the plasma processing apparatus of FIG. 21, where the distance between the facing surface and the substrate mounting surface is set to 7 cm.

FIG. 28B is a view showing a result of calculating an electric field intensity distribution when the distance between the facing surface and the substrate mounting surface is changed in the plasma processing apparatus of FIG. 21, where the distance between the facing surface and the substrate mounting surface is set to 6 cm

FIG. 28C is a view showing a result of calculating an electric field intensity distribution when the distance between the facing surface and the substrate mounting surface is changed in the plasma processing apparatus of FIG. 21, where the distance between the facing surface and the substrate mounting surface is set to 5 cm

FIG. 29A is a view showing a result of calculating an electric field intensity distribution when the distance between the stage and the apex of a conical inner wall surface is changed in the plasma processing apparatus of FIG. 22, where the distance between the stage and the apex of the conical inner wall surface is set to 5 cm.

FIG. 29B is a view showing a result of calculating an electric field intensity distribution when the distance between the stage and the apex of the conical inner wall surface is changed in the plasma processing apparatus of FIG. 22, where the distance between the stage and the apex of the conical inner wall surface is set to 7.5 cm.

FIG. 29C is a view showing a result of calculating an electric field intensity distribution when the distance between the stage and the apex of the conical inner wall surface is changed in the plasma processing apparatus of FIG. 22, where the distance between the stage and the apex of the conical inner wall surface is set to 10 cm.

FIG. 30A is a view showing a result of calculating an electric field intensity distribution when the distance between a facing surface and a substrate mounting surface is changed in the plasma processing apparatus of FIG. 23, where the distance between the facing surface and the substrate mounting surface is set to 7 cm.

FIG. 30B is a view showing a result of calculating an electric field intensity distribution when the distance between the facing surface and the substrate mounting surface is changed in the plasma processing apparatus of FIG. 23, where the distance between the facing surface and the substrate mounting surface is set to 6 cm.

FIG. 30C is a view showing a result of calculating an electric field intensity distribution when the distance between the facing surface and the substrate mounting surface is changed in the plasma processing apparatus of FIG. 23, where the distance between the facing surface and the substrate mounting surface is set to 5 cm.

FIG. 31 is a sectional view schematically showing a configuration of a plasma processing apparatus using a microwave.

### DETAILED DESCRIPTION

Embodiments of the present disclosure will now be described in detail with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

As a result of the inventors' assiduous researches for achieving the above-described objectives, it was found that if a plasma generation device includes a waveguide configured to propagate a microwave, a spherical plasma generation vessel connected to the waveguide, and a dielectric window interposed between the waveguide and the plasma generation vessel to introduce the microwave propagated by the waveguide into the plasma generation vessel, as a radius of the plasma generation vessel is appropriately set, an electromagnetic wave of a specific mode can be excited, and a strong electric field region can be generated in an arbitrary region according to the specific mode. Thus, plasma can be generated in a desired region spaced apart from the dielectric window and positioned around a substrate that is an object to be processed, and as a result, it is possible to prevent the dielectric window from being damaged by the plasma and to generate the plasma in the desired region around the substrate.

The present disclosure is achieved based on the result of the above-described researches.

Hereinafter, a first embodiment of the present disclosure will be described with reference to the drawings.

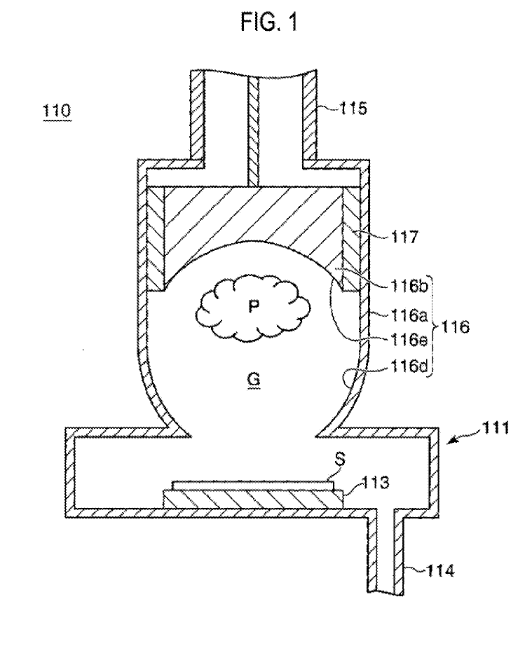

FIG. 1 is a sectional view schematically showing a configuration of a plasma processing apparatus having a plasma generation device according to the first embodiment.

In FIG. 1, a plasma processing apparatus 110 includes a processing chamber (processing vessel) 111 in which plasma processing is performed on a substrate S, and a plasma generation unit (plasma generation device) 112 disposed adjacent to the processing chamber 111.

The processing chamber 111 is provided with a stage 113 to be mounted with the substrate S, and an exhaust pipe 114 is connected to the processing chamber 111. The exhaust pipe 114 is connected to a vacuum pump or a pressure control valve (both not shown), and the vacuum pump or the pressure control valve controls an internal pressure of the processing chamber 111. The stage 113 is provided with a heater or a cooling unit (both not shown) and maintains the mounted substrate S at an appropriate temperature.

The plasma generation unit 112 has a waveguide 115 configured to propagate microwave generated by a microwave generator (not shown), a plasma generation chamber (plasma generation vessel) 116 connected to the waveguide 115, and a dielectric window 117 interposed between the waveguide 115 and the plasma generation chamber 116.

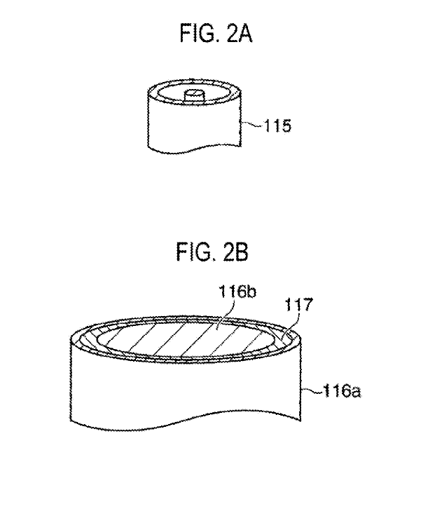

The waveguide 115 is made of a coaxial pipe (see FIG. 2A) or a circular waveguide. In one example, when the waveguide 115 is the circular waveguide, all dimensions of the waveguide 115 are set so that a microwave of a predetermined frequency, e.g., a microwave of 2.45 GHz, can be propagated in the lowest order mode.

The plasma generation chamber 116 has a cylindrical vessel 116a having a lower end in FIG. 1 formed in a hemispherical shape, and a cylindrical member 116b having a lower end in the figure formed in a hemispherical concave portion 116e. The cylindrical member 116b is coaxially accommodated in the cylindrical vessel 116a, and a spherical plasma generation space G (interior of the plasma generation vessel) is defined by the concave portion 116e that is the lower end of the cylindrical member 116b and an inner wall surface 116d that is the lower end of the cylindrical vessel 116a. In addition, the dielectric window 117 is disposed between an inner surface of the cylindrical vessel 116a and a lateral surface of the cylindrical member 116b, i.e., in a gap between an inner wall surface that is an upper end of the cylindrical vessel 116a and an upper end of the cylindrical member 116b (for example, see FIG. 2B).

In the plasma generation chamber 116, a processing gas is introduced from a processing gas introduction port (not shown) into the plasma generation space G. In addition, the lower end of the cylindrical vessel 116a is partially open, so that the plasma generation space G is in communication with the interior of the processing chamber 111. Further, the waveguide 115 is connected to the center of the upper surface of the cylindrical vessel 116a. That is, the waveguide 115 is disposed on the central axis of the cylindrical vessel 116a.

In the plasma generation unit 112, the microwave propagated by the waveguide 115 is introduced into the plasma generation space G through the dielectric window 117. Here, since the dielectric window 117 faces the plasma generation space G along a circumference of the plasma generation space G, i.e., faces the plasma generation space G symmetrically with respect to the central axis of the plasma generation space G, the microwave is introduced symmetrically with respect to the central axis of the plasma generation space G.

Further, since the plasma generation space G is shaped sphere-shaped, an electromagnetic wave of a specific mode can be excited by appropriately setting a radius of the plasma generation space G. As a result, a strong electric field region can be formed in an arbitrary region in the space, e.g., an upper part of the center of the plasma generation space G. In the strong electric field region, since a large amount of energy migrating from the microwave to electrons in plasma causes electron temperature to increase, and thus, electrons having sufficient energy repeatedly collide with atoms or molecules in the processing gas, thereby locally generating high density plasma. That is, since the plasma is actively generated in the strong electric field region more than the other regions, high density plasma P is generated in the region where the strong electric field is generated. In other words, in this embodiment, the plasma P is generated in an arbitrary region from the processing gas only by the introduction of the microwave without using a magnetic field or the like.

Here, since the plasma generation space G of the plasma generation chamber 116 is in communication with the interior of the processing chamber 111, a part of the plasma P generated in the plasma generation space G reaches the substrate S mounted on the stage 113 of the processing chamber 111 and plasma processing is performed on the substrate S. For example, in the plasma processing apparatus 110, a mixture gas containing hydrogen gas, a carbon-containing gas such as methane gas, propane gas or acetylene gas, and an impurity-containing gas such as phosphine gas or diborane gas may be used as the processing gas. For example, in the plasma processing apparatus 110, the plasma generation space G or the interior of the processing chamber 111 is maintained at a pressure of 10 to 200 Torr. For example, in the plasma processing apparatus 110, by heating the substrate S at 700 to 1200 degrees C. using the stage 113, a diamond film is grown on the substrate S by radicals in the plasma P generated from the processing gas.

According to the plasma processing apparatus 110 of FIG. 1, the plasma generation space G of the plasma generation chamber 116, into which the microwave is introduced, is sphere-shaped. In this case, the electromagnetic wave of the specific mode can be excited by appropriately setting the radius of the plasma generation space G. The strong electric field region can be generated in an arbitrary region according to the specific mode, and thus, the plasma P can be generated in a region spaced apart from the dielectric window 117. As a result, it is possible to prevent the dielectric window 117 from being damaged by the plasma P.

In the plasma processing apparatus 110, the microwave is introduced symmetrically with respect to the central axis of the plasma generation space G. Therefore, it is easy to set a radius necessary for exciting the electromagnetic wave of the specific mode, and to predict the region in which the strong electric field region is generated, and therefore, the region of the plasma P to be generated can be easily controlled.

In this embodiment, the plasma generation space G of the plasma processing apparatus 110 allows the strong electric field region to be generated in an arbitrary region according to a mode. It is considered that a main factor for the strong electric field region is that the inner wall surface 116d as the lower end of the cylindrical vessel 116a and the concave portion 116e as the lower end of the cylindrical member 116b, which are boundary conditions of the microwave, are hemisphere-shaped and a mode of the excited electromagnetic wave can be specified by adjusting a radius thereof. Therefore, the plasma generation space G needs only to be sphere-shaped. For example, even if the microwave is not introduced symmetrically with respect to the central axis of the plasma generation space G, an approximately local strong electric field region can be generated in an arbitrary region of the plasma generation space G.

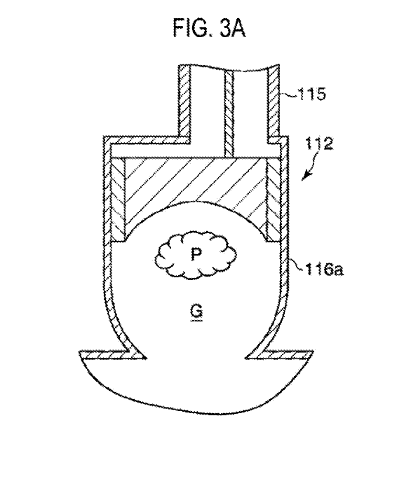

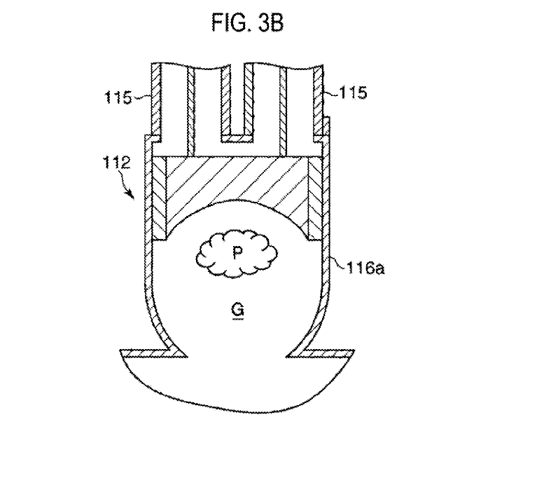

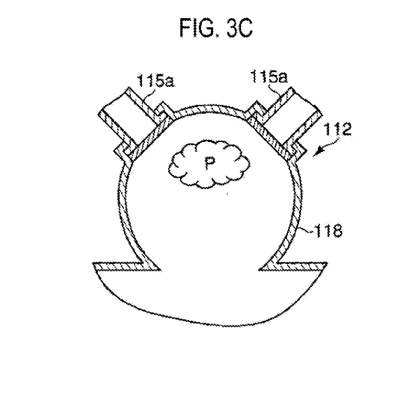

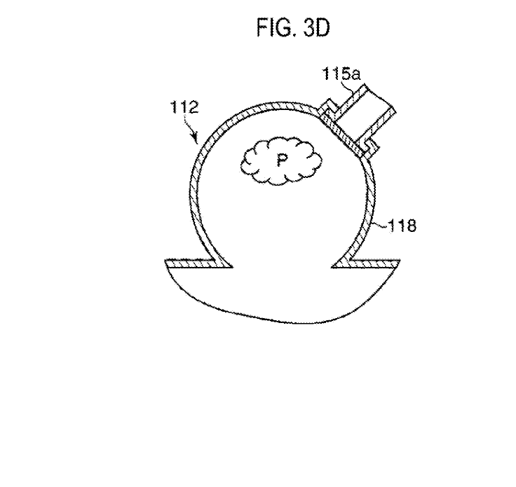

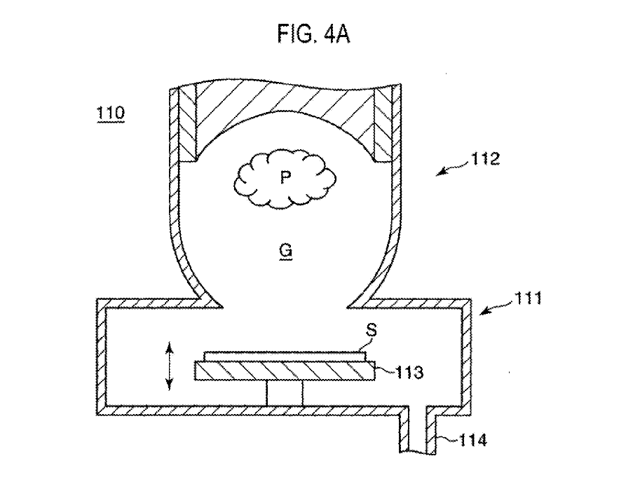

For the above-described reasons, there is a degree of freedom in disposing the waveguide 115. That is, although the plasma processing apparatus 110 of FIG. 1 includes the waveguide 115 to be disposed on the central axis of the cylindrical vessel 116a, the waveguide 115 need not be disposed on the central axis of the cylindrical vessel 116a. For example, one waveguide 115 may be disposed offset from the central axis of the cylindrical vessel 116a as shown in FIG. 3A, or a plurality, e.g., two, of waveguides 115 may be disposed offset from the central axis of the cylindrical vessel 116a as shown in FIG. 3B.

In addition, the microwave need not be introduced into the plasma generation space G through the dielectric window 117. For example, as shown in FIG. 3C, the plasma generation unit 112 may include a spherical plasma generation chamber 118, and a plurality, e.g., two, of waveguides 115a mounted to the plasma generation chamber 118 so as to be directed to the center of the plasma generation chamber 118. Alternatively, as shown in FIG. 3D, the plasma generation unit 112 may include a spherical plasma generation chamber 118, and a waveguide 115a mounted to the plasma generation chamber 118 so as to be directed to the center of the plasma generation chamber 118. Also, in the plasma generation unit 112 shown in FIG. 3C or 3D, since the plasma generation chamber 118 is sphere-shaped, it is possible to generate an approximately local strong electric field region in an arbitrary region in the plasma generation chamber 118.

In addition, it is preferable that in the plasma generation unit 112 of FIG. 3B or 3C having the plurality of waveguides 115 or 115a, the respective waveguides 115 or 115a be disposed symmetrically with respect to the central axis of the cylindrical vessel 116a or the central axis of the plasma generation chamber 118. With this configuration, the microwave can be introduced into the plasma generation space G or the plasma generation chamber 118 symmetrically with respect to each central axis as a result, and thus, the generation region of the plasma P can be easily controlled.

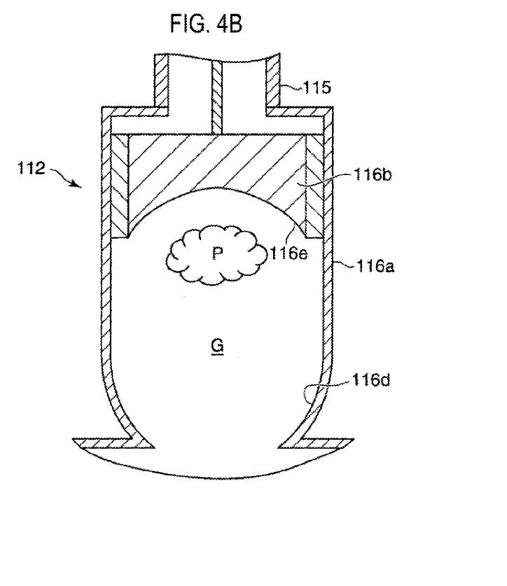

Further, the plasma processing apparatus 110 may be configured so that the stage 113 in the processing chamber 111 may be moved in the up and down direction as shown by an arrow in FIG. 4A. With this configuration, the distance between the plasma P and the substrate S can be controlled, and thus, when a film is formed using the plasma P, a film forming rate or a film thickness distribution on the substrate S can be controlled. In addition, when etching is performed using the plasma P, an etching rate or an etching rate distribution on the substrate S can be controlled.

In addition, the cylindrical vessel 116a may be configured to be elongated downward, as shown in FIG. 4B, so that the plasma generation space G may consist of a cylindrical space and hemispherical spaces positioned above and below the cylindrical space, instead of the spherical space. Even in such a case, since the inner wall surface 116d that is the lower end of the cylindrical vessel 116a and the concave portion 116e that is the lower end of the cylindrical member 116b are hemisphere-shaped, the strong electric field region can be generated in a specific region by appropriately setting the radii of the spaces or the height of the cylindrical space. As a result, it is possible to generate a local strong electric field region in an arbitrary region in the plasma generation space G.

Hereinabove, while the present disclosure has been described using the above-described embodiment, the present disclosure is not limited to the above-described embodiment.

Although the plasma generation space G is spherical in the above embodiment, the plasma generation space G may be configured to have a polyhedron approximate to a sphere or a spatial shape defined by a curved surface represented by a higher order function.

### Example

Next, examples of the present disclosure will be described.

First, in order to evaluate influences of a difference in shape of the plasma generation space G on a generation pattern of the local strong electric field region, 2-dimensional models of Examples 1 and 2 were prepared based on the plasma generation unit 112 of FIG. 1. For example, the radius of the plasma generation space G was set to 5.5 cm in Example 1 and the radius of the plasma generation space G was set to 8 cm in Example 2.

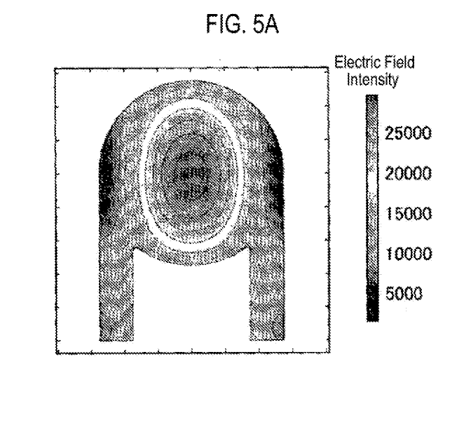

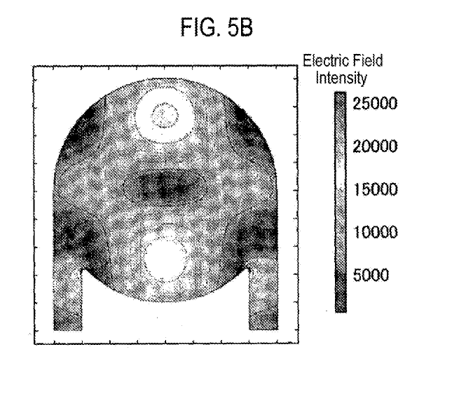

Successively, on the assumption that low density plasma having a uniform distribution of nₑ=10¹⁶ m⁻³, which meets ω>ωₚₑ, has already existed in the plasma generation space G (wherein ω designates a microwave (angular) frequency, ωₚₑ designates an electron plasma (angular) frequency and nₑ designates an electron density) and momentum transfer collision frequency νₘ is equal to ω, electric field intensity distributions were calculated in Examples 1 and 2 using an electronic computation module produced by COMSOL Inc., and the results thereof are shown in FIGS. 5A and 5B. Here, FIG. 5A shows an electric field intensity distribution in Example 1, and FIG. 5B shows an electric field intensity distribution in Example 2.

As shown in FIGS. 5A and 5B, it was seen that if the plasma generation space G is sphere-shaped, it is possible to generate the local strong electric field region even though the shape of the plasma generation space G is changed. In addition, it was also seen that if the shape of the plasma generation space G is changed, the shape of the generated local strong electric field region is changed. Accordingly, it was assumed that the shape of the plasma generation space G is a main factor in generating the local strong electric field region.

Then, in order to evaluate the influences on a generation pattern of the local strong electric field region when the plasma generation space G is in communication with the interior of the processing chamber 111, 2-dimensional models of Examples 3 to 5 were prepared based on the plasma generation unit 112 and the processing chamber 111 of FIG. 1. For example, the stage 113 was not installed in Example 3, the distance from the stage 113 to an the upper inner surface of the processing chamber 111 was set to 2 cm in Example 4, and the distance from the stage 113 to the upper inner surface of the processing chamber 111 was set to 1.5 cm in Example 5.

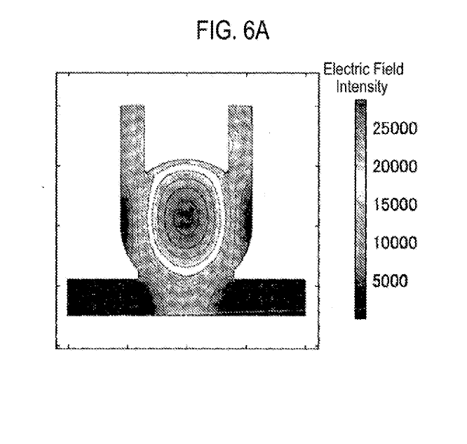

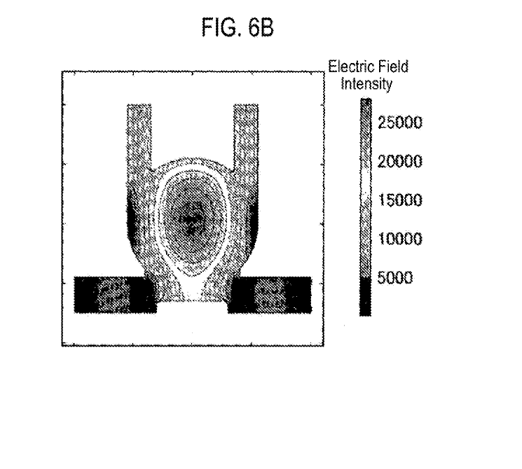

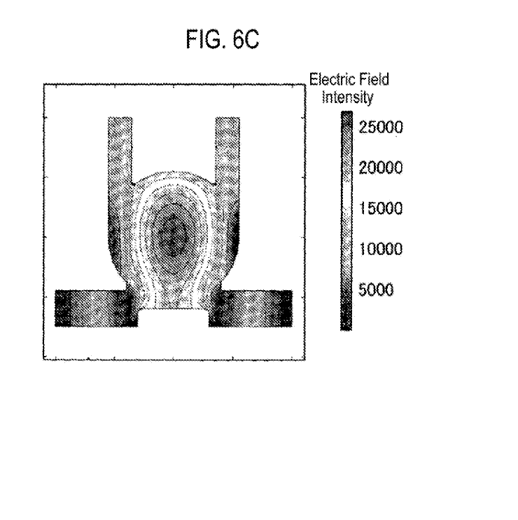

Next, under the same conditions as Examples 1 and 2, electric field intensity distributions were calculated in Examples 3 to 5 using the same electronic computation module produced by COMSOL Inc., and the results thereof are shown in FIGS. 6A to 6C. Here, FIG. 6A shows an electric field intensity distribution in Example 3, FIG. 6B shows an electric field intensity distribution in Example 4, and FIG. 6C shows an electric field intensity distribution in Example 5.

As shown in FIGS. 6A to 6C, it was seen that if the plasma generation space G is sphere-shaped, it is possible to generate the local strong electric field region even though the plasma generation space G is in communication with the interior of the processing chamber 111. Accordingly, it was also assumed that the shape of the plasma generation space G is a main factor in generating the local strong electric field region. In addition, it was also seen that the local strong electric field region is hardly changed even if the stage 113 is moved up and down. Accordingly, it is expected that a desired film forming rate or etching rate can be easily realized only by moving the stage 113 up and down.

In addition, as a result of the inventors' assiduous researches for achieving the above-described objective, it was found that if a plasma generation device includes a waveguide configured to propagate a microwave, a plasma generation vessel having a hemispherical curved space portion and connected to the waveguide, and a dielectric window interposed between the waveguide and the plasma generation vessel to introduce the microwave propagated by the waveguide into the plasma generation vessel, as inner and outer diameters of the hemispherical curved space portion that are boundary conditions of the electromagnetic wave are appropriately set, an electromagnetic wave of a specific mode can be excited, and a strong electric field region can be generated in an arbitrary region according to the specific mode. Thus, plasma can be generated in a desired region spaced apart from the dielectric window and positioned around a substrate that is an object to be processed. As a result, it is possible to prevent the dielectric window from being damaged by the plasma and to generate the plasma in the desired region around the substrate.

The present disclosure is achieved based on the result of the above-described researches.

Hereinafter, a second embodiment of the present disclosure will be described with reference to the drawings.

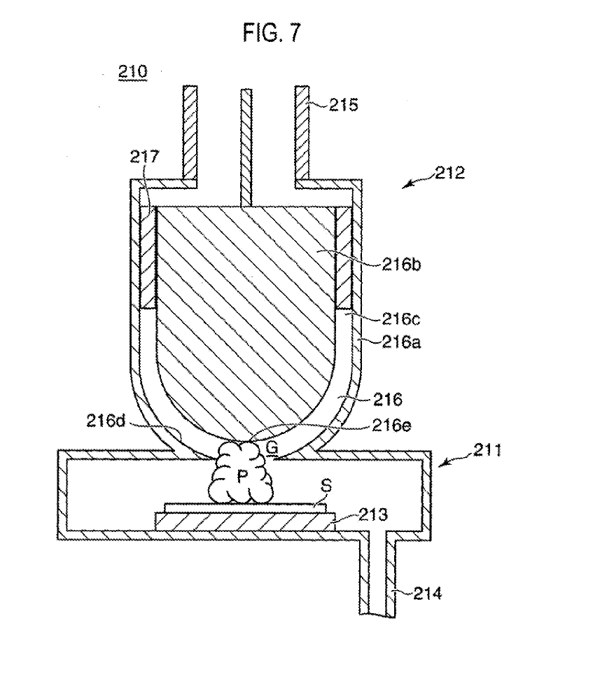

FIG. 7 is a sectional view schematically showing a configuration of a plasma processing apparatus having a plasma generation device according to the second embodiment.

In FIG. 7, a plasma processing apparatus 210 includes a processing chamber (processing vessel) 211 in which plasma processing is performed on a substrate S, and a plasma generation unit (plasma generation device) 212 disposed adjacent to the processing chamber 211.

The processing chamber 211 is provided with a stage 213 to be mounted with the substrate S, and an exhaust pipe 214 is connected to the processing chamber 211. The exhaust pipe 214 is connected to a vacuum pump or a pressure control valve (both not shown), and the vacuum pump or the pressure control valve controls an internal pressure of the processing chamber 211. The stage 213 is provided with a heater or a cooling unit (both not shown), which controls the mounted substrate S to be at an appropriate temperature.

The plasma generation unit 212 has a waveguide 215 configured to propagate a microwave generated by a microwave generator (not shown), a plasma generation chamber (plasma generation vessel) 216 connected to the waveguide 215, and a dielectric window 217 interposed between the waveguide 215 and the plasma generation chamber 216.

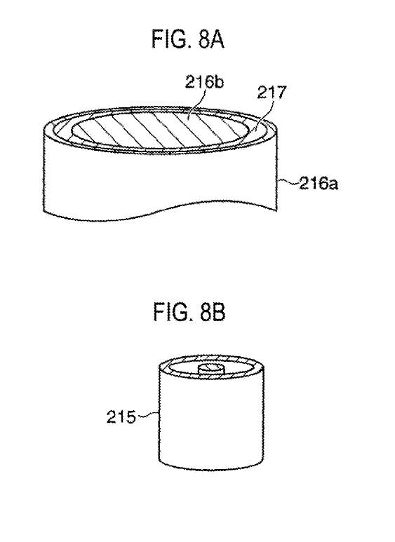

The waveguide 215 is made of a coaxial pipe (see FIG. 8B) or a circular waveguide. For example, when the waveguide 215 is the circular waveguide, all dimensions of the waveguide 215 are set so that a microwave of a predetermined frequency, e.g., a microwave of 2.45 GHz, can be propagated in the lowest order mode.

Returning to FIG. 7, the plasma generation chamber 216 has a hemispherical curved space portion, which is positioned between a cylindrical vessel 216a having a lower end in FIG. 7 formed in a hemispherical shape and a cylindrical member 216b having a lower end in the figure formed in a hemispherical convex portion 216e. That is, the cylindrical member 216b is coaxially accommodated in the cylindrical vessel 216a, and a plasma generation space G (an interior of the plasma generation vessel) is defined as the hemispherical curved space portion by the convex portion 216e that is the lower end of the cylindrical member 216b and an inner wall surface 216d that is the lower end of the cylindrical vessel 216a. In addition, the dielectric window 217 is disposed in a gap between an inner surface of the cylindrical vessel 216a and a lateral surface of the cylindrical member 216b (for example, see FIG. 8A).

In the present embodiment, the hemispherical curved space portion refers to a space portion provided between the curved surface 216e of a hemispherical body and the inner curved surface 216d of a hollow hemispherical body, which faces the hemispherical body with a predetermined interval therebetween. The hollow hemispherical body has a diameter larger than that of the hemispherical body and is disposed concentrically with the hemispherical body.

A processing gas is introduced from a processing gas introduction port (not shown) into the plasma generation space G as the plasma generation chamber 216. In addition, the lower end of the cylindrical vessel 216a is partially open, so that the plasma generation space G is in communication with the interior of the processing chamber 211. Further, the waveguide 215 is connected to the center of the upper surface of the cylindrical vessel 216a. That is, the waveguide 215 is disposed on the central axis of the cylindrical vessel 216a.

In the plasma generation unit 212, the microwave propagated by the waveguide 215 is introduced into a plasma introduction passage 216c through the dielectric window 217, and the microwave introduced into the plasma introduction passage 216c is further introduced into the plasma generation space G. Here, since the plasma introduction passage 216c is formed symmetrically with respect to the central axis of the plasma generation space G, the microwave is introduced symmetrically with respect to the central axis of the plasma generation space G.

Since the plasma generation space G has the hemispherical curved space portion, an electromagnetic wave of a specific mode can be excited by appropriately setting inner and outer diameters of the hemispherical curved space portion. As a result, a strong electric field region can be formed in an arbitrary region in the space, e.g., the center of the plasma generation space G. In the strong electric field region, since a large amount of energy migrating from the microwave to electrons causes electron temperature to be high, and thus, electrons having sufficient energy repeatedly collide with atoms or molecules in the processing gas, thereby locally generating high density plasma. That is, since the plasma is actively generated in the strong electric field region more than the other regions, high density plasma P is generated in the region where the strong electric field is generated. In other words, in this embodiment, the plasma P is generated from the processing gas only by introducing the microwave without using a magnetic field or the like.

Here, since the plasma generation space G as the plasma generation chamber 216 is in communication with the interior of the processing chamber 211, a part of the plasma P generated in the plasma generation space G reaches the substrate S mounted on the stage 213 of the processing chamber 211 and plasma processing is performed on the substrate S. For example, in the plasma processing apparatus 210, a mixture gas containing hydrogen gas, a carbon-containing gas such as methane gas, propane gas or acetylene gas, and an impurity-containing gas such as phosphine gas or diborane gas may be used as the processing gas, and by maintaining the plasma generation space G or the interior of the processing chamber 211 at a pressure of 10 to 200 Torr and heating the substrate S at 700 to 1200 degrees C. using the stage 213, a diamond film is grown on the substrate S by radicals in the plasma P generated from the processing gas.

According to the plasma processing apparatus 210 of FIG. 7, since the plasma generation space G as the plasma generation chamber 216, into which the microwave is introduced, has the hemispherical curved space portion, the electromagnetic wave of the specific mode can be excited by appropriately setting the inner and outer diameters of the hemispherical curved space portion, and the strong electric field region can be generated in an arbitrary region according to the specific mode. Thus, the plasma P can be generated in a region spaced apart from the dielectric window 217. As a result, it is possible to prevent the dielectric window 217 from being damaged by the plasma P.

Further, in the plasma processing apparatus 210, since the microwave is introduced symmetrically with respect to the central axis of the plasma generation space G, it is easy to appropriately set the inner and outer diameters of the hemispherical curved space portion necessary for exciting the electromagnetic wave of the specific mode and to predict the region in which the strong electric field region is generated, and therefore, the region of the plasma P to be generated can be easily controlled.

In the plasma processing apparatus 210, since the inner wall surface 216d as the lower end of the cylindrical vessel 216a which is a boundary condition of the microwave is hemisphere-shaped, a mode of an electromagnetic wave can be specified by the inner and outer diameters of the hemispherical curved space portion, which is thought to be a main factor of the generation of the local strong electric field region according to the mode in the plasma generation space G. Therefore, if the plasma generation space G only has the hemispherical curved space portion, regardless of any type of the introduction of the microwave into the plasma generation space G, for example, even if the microwave is not introduced symmetrically with respect to the center of the plasma generation space G, an approximately local strong electric field region can be generated in an arbitrary region of the plasma generation space G.

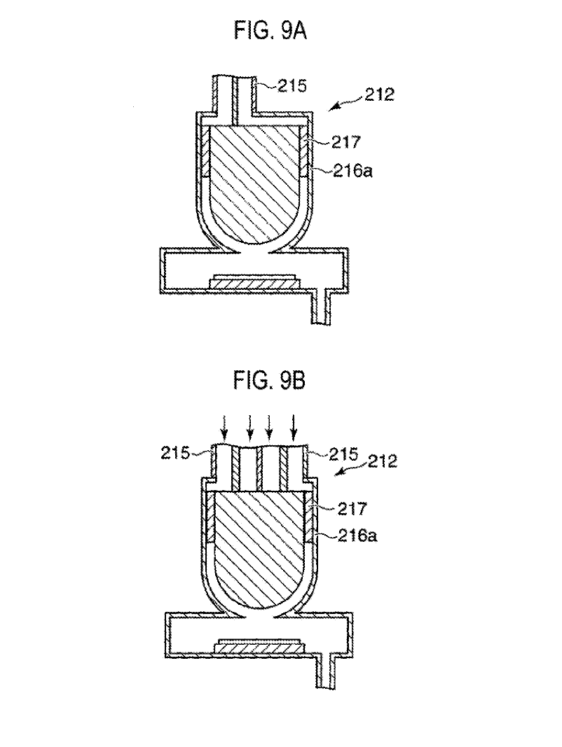

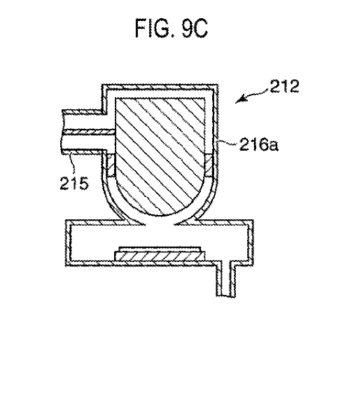

For the above-described reasons, there is a degree of freedom in disposing the waveguide 215. Although the plasma processing apparatus 210 of FIG. 7 includes the waveguide 215 to be disposed on the central axis of the cylindrical vessel 216a, the waveguide 215 need not be disposed on the central axis of the cylindrical vessel 216a. For example, one waveguide 215 may be disposed offset from the central axis of the cylindrical vessel 216a as shown in FIG. 9A, or a plurality, e.g., two, of waveguides 215 may be disposed offset from the central axis of the cylindrical vessel 216a as shown in FIG. 9B. In addition, as shown in FIG. 9C, one waveguide 215 may be disposed in a lateral surface of the cylindrical vessel 216a.

Also, in the plasma generation unit 212 shown in FIGS. 9A to 9C, since the plasma generation space G has the hemispherical curved space portion, an approximately local strong electric field region can be generated in an arbitrary region inside the plasma generation space G.

In addition, when the plurality of waveguides 215 are provided in the plasma generation unit 212 of FIG. 9B, it is preferable that the respective waveguides 215 be disposed symmetrically with respect to the central axis of the cylindrical vessel 216a. With this configuration, the microwave can be introduced symmetrically with respect to the central axis of the plasma generation space G as a result, and the region of the plasma P to be generated can be easily controlled.

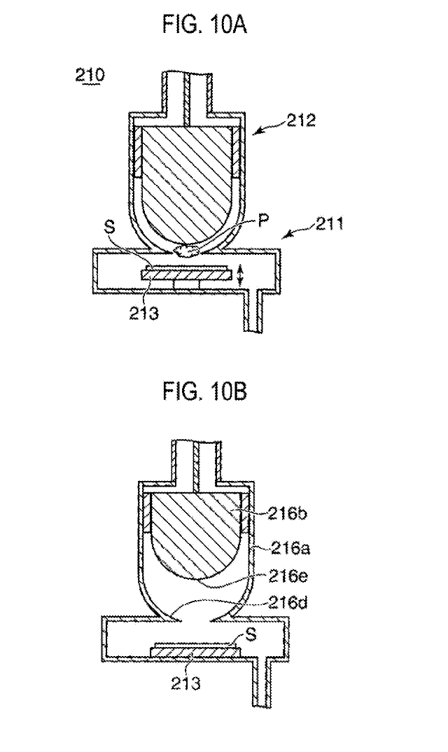

Further, in the plasma processing apparatus 210, the stage 213 in the processing chamber 211 may be configured to be moved in the up and down direction as shown in FIG. 10A. With this configuration, the distance between the plasma P and the substrate S can be controlled, and thus, when a film is formed using the plasma P, a film forming rate or a film thickness distribution on the substrate S can be controlled. In addition, it is thought that when etching is performed using the plasma P, an etching rate or an etching rate distribution on the substrate S can be controlled.

Also, as shown in FIG. 10B, the internal volume of the plasma generation space G may be increased by widening the gap between the convex portion 216e that is the lower end of the cylindrical member 216b and the inner wall surface 216d that is the lower end of the cylindrical vessel 216a. Even in such a case, since the inner wall surface 216d that is the lower end of the cylindrical vessel 216a is hemisphere-shaped, which is the boundary condition, it is expected that a standing wave can be formed, and it is thought that the local strong electric field region can be generated in the plasma generation space G by adjusting a shape of the hemispherical curved space portion.

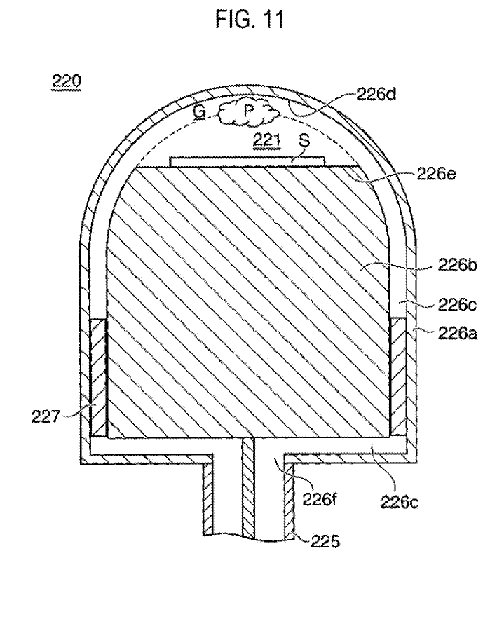

FIG. 11 is a sectional view schematically showing a configuration of a plasma processing apparatus having a plasma generation device according to a third embodiment of the present disclosure. In this plasma processing apparatus, a processing chamber (processing vessel) configured to perform plasma processing on a substrate S and a plasma generation space G of a plasma generation device are integrated.

In FIG. 11, a plasma processing apparatus 220 has a cylindrical vessel 226a having an upper end in FIG. 11 formed in a hemispherical shape, and a cylindrical member 226b having an upper plane (stage) 226e formed by horizontally truncating a hemispherical convex portion of an upper end thereof in the figure. The cylindrical member 226b is coaxially accommodated in the cylindrical vessel 226a, and a hemispherical space portion is defined between the stage 226e of the cylindrical member 226b and an inner wall surface 226d that is the upper end of the cylindrical vessel 226a. This hemispherical space portion is configured in such a manner that a plasma generation space G consisting of a hemispherical curved space portion and a processing chamber 221 consisting of a hemispherical space portion corresponding to the convex portion truncated from the cylindrical member 226b are integrated. In addition, a dielectric window 227 is disposed between an inner side surface of the cylindrical vessel 226a and a lateral surface of the cylindrical member 226b.

In the plasma processing apparatus 220, a processing gas is introduced from a processing gas introduction port (not shown) into the plasma generation space G integrated with the processing chamber 221 configured to perform the plasma processing. The cylindrical vessel 226a has an opening 226f in a central portion of a lower end thereof and a waveguide 225 is connected to the opening 226f.

In the plasma processing apparatus 220, the microwave propagated by the waveguide 225 is introduced into an introduction passage 226c through the dielectric window 227, and the microwave introduced into the introduction passage 226c is further introduced into the plasma generation space G. Since the introduction passage 226c is disposed symmetrically with respect to the central axis of the plasma generation space G, the microwave is introduced symmetrically with respect to the center of the plasma generation space G.

Since the plasma generation space G is provided with the hemispherical curved space portion, an electromagnetic wave of a specific mode can be excited by appropriately setting inner and outer diameters of the hemispherical curved space portion, and a local strong electric field region is generated in an arbitrary region according to the specific mode, e.g., in the center of the plasma generation space G.

Here, since the plasma generation space G and the processing chamber 221 are integrated, a part of the plasma P generated in the plasma generation space G reaches the substrate S mounted on the stage 226e of the processing chamber 221, and plasma processing is performed on the substrate S, in the same way as the embodiment of FIG. 7.

According to the plasma processing apparatus 220 of FIG. 11, since the processing chamber (processing vessel) 221 configured to perform plasma processing on the substrate S and the plasma generation space G in the plasma generation device are integrated and the plasma generation space G has the hemispherical curved space portion, the strong electric field region can be generated in an arbitrary region of the plasma generation space G, and thus, the plasma P can be generated in a region spaced apart from the dielectric window 227. As a result, the dielectric window 227 can be prevented from being damaged by the plasma P.

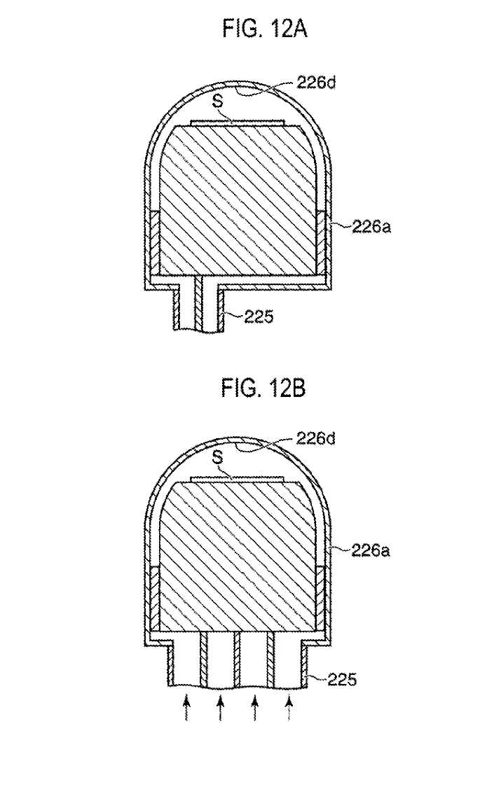

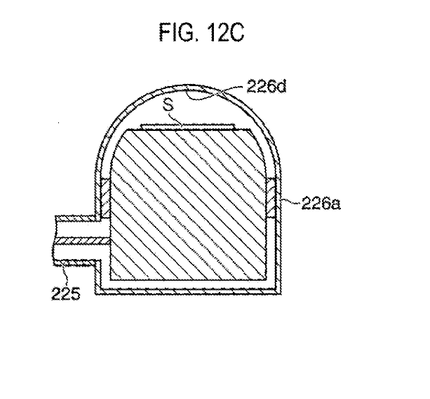

FIGS. 12A to 12C are views showing modified examples of the plasma processing apparatus of the above third embodiment. In this embodiment, in the same way as the embodiment illustrated in FIG. 7, there is a degree of freedom in disposing the waveguide 225. For example, one waveguide 225 may be disposed offset from the central axis of the cylindrical vessel 226a as shown in FIG. 12A, or a plurality, e.g., two, of waveguides 225 may be disposed offset from the central axis of the cylindrical vessel 226a as shown in FIG. 12B. In addition, as shown in FIG. 12C, one waveguide 225 may be disposed in a lateral surface of the cylindrical vessel 226a.

Even in such cases, the inner wall surface 226d that is the upper end of the cylindrical vessel 226a is a hemispherical surface, which is the boundary condition of the electromagnetic wave, and as a result, it is thought that the local strong electric field region can be generated in the plasma generation space G.

Hereinabove, while the present disclosure has been described using the second and third embodiments, the present disclosure is not limited to the second and third embodiments.

### Example

Next, examples of the present disclosure will be described.

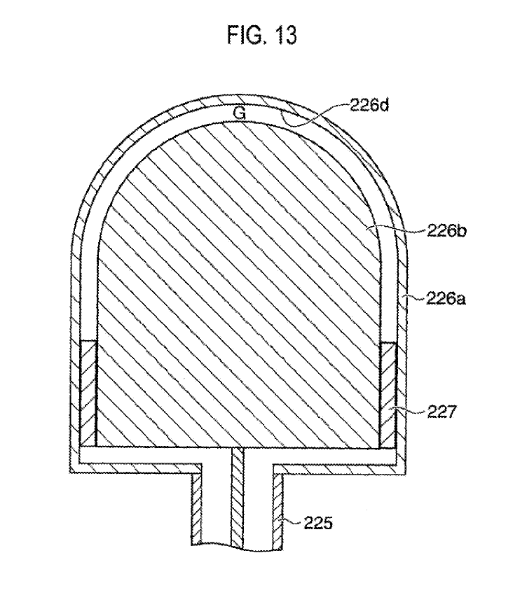

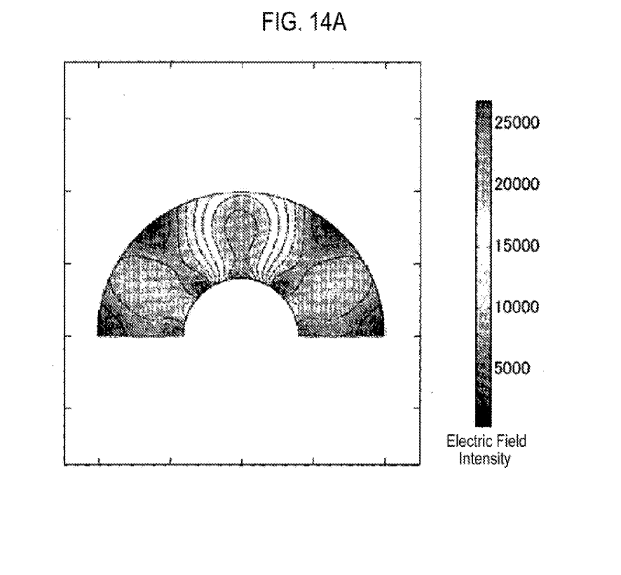

First, in order to evaluate the influences of a difference in shape of the plasma generation space G on a generation pattern of the local strong electric field region, 2-dimensional models of Examples 6 and 7 were prepared based on the plasma generation unit in which in the plasma processing apparatus 220 (see FIG. 11), the upper end of the cylindrical member 226b had a convex shape and the stage 226e was not installed as shown in FIG. 13. For example, the plasma generation space G had an outer hemisphere radius of 10 cm and an inner hemisphere radius of 4 cm in Example 6 and the plasma generation space G had an outer hemisphere radius of 10 cm and an inner hemisphere radius of 8 cm in Example 7.

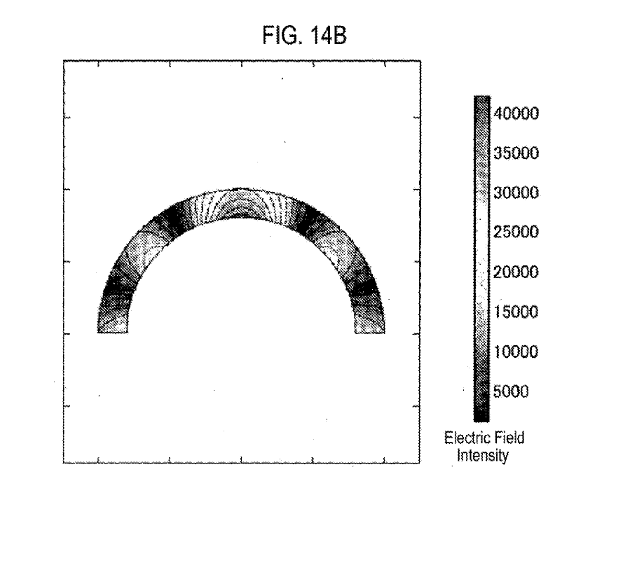

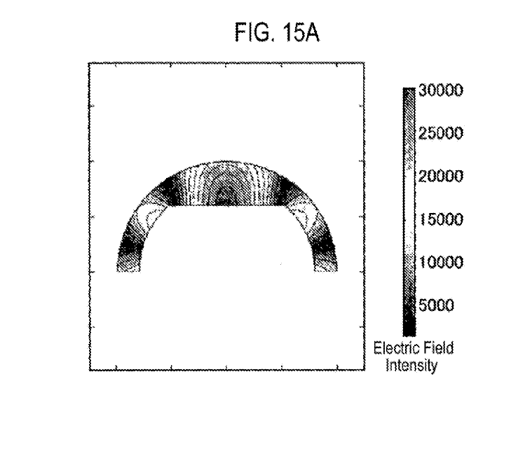

Successively, on the assumption that low density plasma having a uniform distribution of nₑ=10¹⁶ m⁻³, which meets ω>ωₚₑ, has already existed in the plasma generation space G (wherein ω designates a microwave (angular) frequency, ωₚₑ designates an electron plasma (angular) frequency, and nₑ designates an electron density) and momentum transfer collision frequency νₘ is equal to ω, electric field intensity distributions were calculated in Examples 6 and 7 using an electronic computation module produced by COMSOL Inc., and the results thereof are shown in FIGS. 14A and 14B. Here, FIG. 14A shows an electric field intensity distribution in Example 6, and FIG. 14B shows an electric field intensity distribution in Example 7.

As shown in FIGS. 14A and 14B, it was seen that if the plasma generation space G has the hemispherical curved space portion, it is possible to generate the local strong electric field region even though the shape of the plasma generation space G is changed. In addition, it was also seen that if the shape of the plasma generation space G is changed, the shape of the generated local strong electric field region is changed. Accordingly, it was assumed that the shape of the plasma generation space G is a main factor in generating the local strong electric field region.

Then, in order to evaluate the influences on a generation pattern of the local strong electric field region when the processing chamber was provided inside the plasma generation space G and the plasma generation space G and the processing chamber were integrated, 2-dimensional models of Examples 8 to 10 were prepared based on the plasma processing apparatus 220 of FIG. 11. In Example 8, the stage 226e was installed on the upper end of the cylindrical member 226b and also a concave portion was provided in the stage 226e in order to evaluate influences of a gap between the plasma P and the substrate S. The depth from the surface of the stage 226e to the bottom of the concave portion mounted with the substrate S was set to 2 cm in Example 9, and the depth from the surface of the stage 226e to the bottom of the concave portion mounted with the substrate S was set to 3 cm in Example 10.

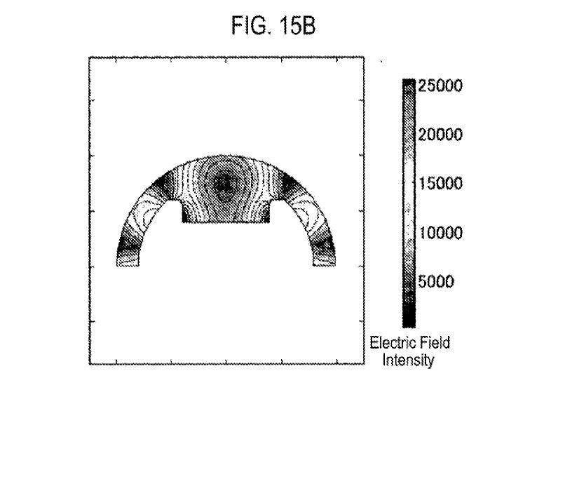

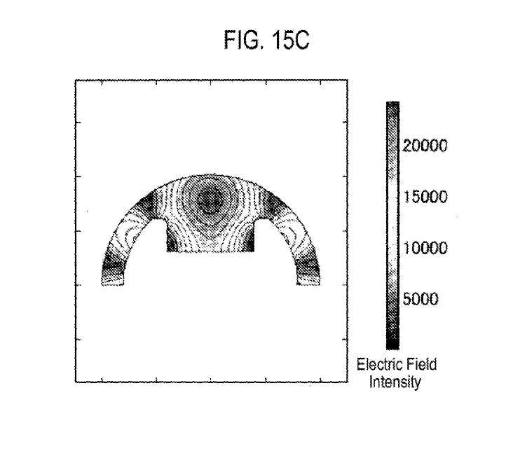

Then, under the same conditions as Examples 6 and 7, electric field intensity distributions were calculated in Examples 8 to 10 using the same electronic computation module produced by COMSOL Inc., and the results thereof are shown in FIGS. 15A to 15C. Here, FIG. 15A shows an electric field intensity distribution in Example 8, FIG. 15B shows an electric field intensity distribution in Example 9, and FIG. 15C shows an electric field intensity distribution in Example 10.

As shown in FIGS. 15A to 15C, it was seen that if the plasma generation space G has the hemispherical curved space portion, it is possible to generate the local strong electric field region even though the plasma generation space G and the processing chamber 221 are integrated. Accordingly, it was also assumed that the shape of the plasma generation space G is a main factor in the generation of the local strong electric field region. In addition, it was also seen that the local strong electric field region is hardly changed although the stage 226e is moved up and down. Accordingly, there is a possibility of easily realizing a desired film forming rate or etching rate only by moving the stage 226e up and down.

Next, in order to evaluate influences on a generation pattern of the local strong electric field region when the processing chamber was connected to an outer curved portion of the plasma generation space G, 2-dimensional models of Examples 11 to 13 were prepared based on the plasma processing apparatus 210 of FIG. 7.

In Example 11, in the plasma processing apparatus 210, an outside (a lower side in FIG. 7) of the plasma generation space G was connected to the processing chamber (processing vessel) 211 (see FIG. 7). In Examples 12 and 13, the stage 213 of FIG. 7 was installed to be moved up and down in order to evaluate influences of a gap between the plasma P and the substrate S in the plasma processing apparatus of FIG. 7. For example, a gap from an upper end of the chamber 211 to the surface of the stage 213 was set to 2.5 cm in Example 12 and a gap from the upper end of the chamber 211 to the surface of the stage 213 was set to 1.5 cm in Example 13.

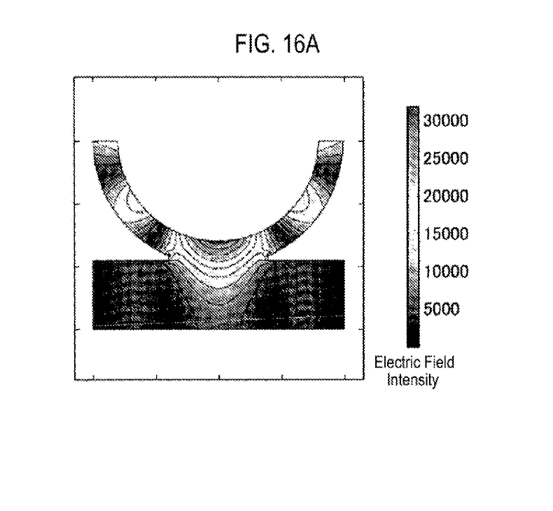

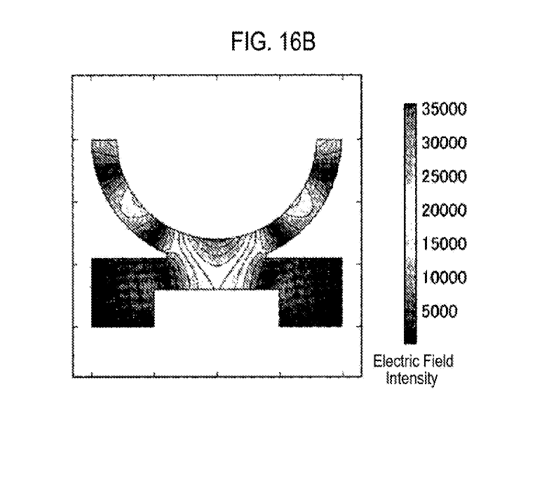

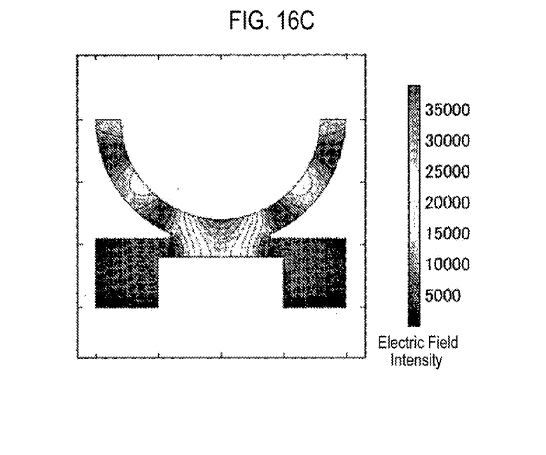

Next, under the same conditions as Examples 6 to 10, electric field intensity distributions were calculated in Examples 11 to 13 using the same electronic computation module produced by COMSOL Inc., and the results thereof are shown in FIGS. 16A to 16C. Here, FIG. 16A shows an electric field intensity distribution in Example 11, FIG. 16B shows an electric field intensity distribution in Example 12, and FIG. 16C shows an electric field intensity distribution in Example 13.

As shown in FIGS. 16A to 16C, it was seen that if the plasma generation space G has the hemispherical curved space portion, it is possible to generate the local strong electric field region even though the plasma generation space G is in communication with the processing chamber 211. Accordingly, it was also assumed that the shape of the plasma generation space G is a main factor in the generation of the local strong electric field region. In addition, it was also seen that the local strong electric field region is hardly changed although the stage 213 is moved up and down. Accordingly, there is a possibility of easily realizing a desired film forming rate or etching rate only by moving the stage 213 up and down.

In addition, as a result of the inventors' assiduous researches for achieving the above-described object, it was found that if a plasma processing device includes a waveguide configured to propagate a microwave, a plasma generation vessel connected to the waveguide, a mounting table disposed in the plasma generation vessel and mounted with a substrate, and a dielectric window interposed between the waveguide and the plasma generation vessel to introduce the microwave propagated by the waveguide into the plasma generation vessel, and the plasma generation vessel has a central axis and has a shape symmetric with respect to the central axis, as an inner diameter of a shape, e.g., a hemisphere, of the plasma generation vessel is appropriately set, an electromagnetic wave of a specific mode can be excited, and a strong electric field region can be generated in an arbitrary region according to the specific mode. Thus, plasma can be generated in a desired region spaced apart from the dielectric window and positioned around a substrate that is an object to be processed, and as a result, it is possible to prevent the dielectric window from being damaged by the plasma and to generate the plasma in the desired region around the substrate. The present disclosure is achieved based on the result of the above-described researches.

Hereinafter, a fourth embodiment of the present disclosure will be described with reference to the drawings.

First, a plasma processing apparatus according to the fourth embodiment of the present disclosure will be described.

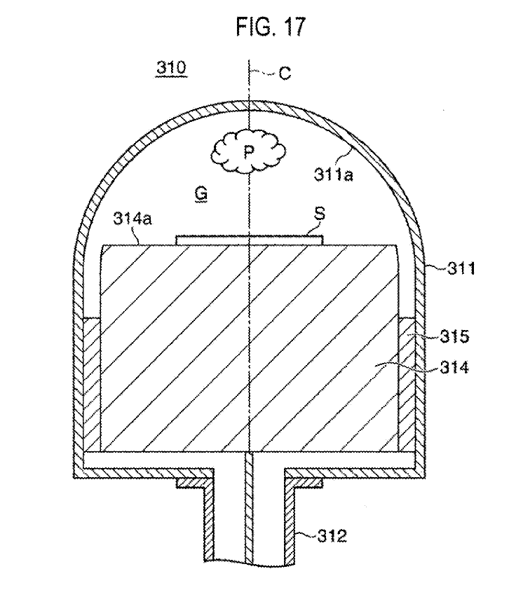

FIG. 17 is a sectional view schematically showing a configuration of the plasma processing apparatus according to this embodiment.

In FIG. 17, a plasma processing apparatus 310 includes a processing chamber (plasma generation vessel) 311 in which a plasma processing is performed on a substrate S, and a waveguide 312 configured to propagate a microwave generated by a microwave generator (not shown).

The processing chamber 311 is provided with a stage 314 having a substrate mounting surface 314a on which a substrate S is mounted, and an exhaust pipe (not shown) is connected to the processing chamber 311. The exhaust pipe is connected to a vacuum pump or a pressure control valve (both not shown), and the vacuum pump or the pressure control valve controls an internal pressure of the processing chamber 311. The stage 314 is provided with a heater or a cooling unit (both not shown), which controls the mounted substrate S to an appropriate temperature.

The waveguide 312 includes a coaxial pipe or a circular waveguide, and when the waveguide 312 is the circular waveguide, all dimensions thereof are set so that a microwave of a predetermined frequency, e.g., a microwave of 2.45 GHz, can be propagated in the lowest order mode.

The processing chamber 311 has a central axis C, has a shape symmetrical with respect to the central axis C, and has an upper end side in FIG. 17 formed in the hemisphere-shape and a lower end side in the figure formed in the shape of a cylinder. The stage 314 is shaped in a cylinder and is disposed coaxially with the processing chamber 311 in the processing chamber 311. A hemispherical inner wall surface 311a of the processing chamber 311 and the substrate mounting surface 314a of the stage 314 define a plasma generation space G. A processing gas is introduced into the plasma generation space G from a processing gas introduction port (not shown).

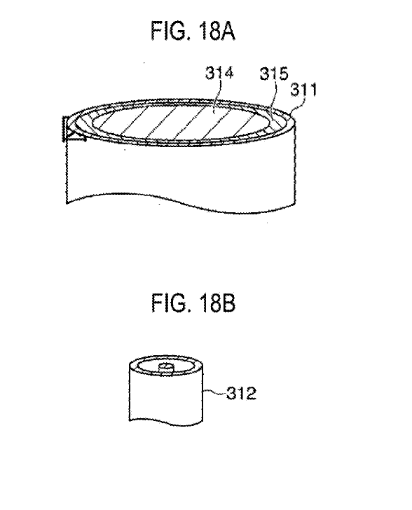

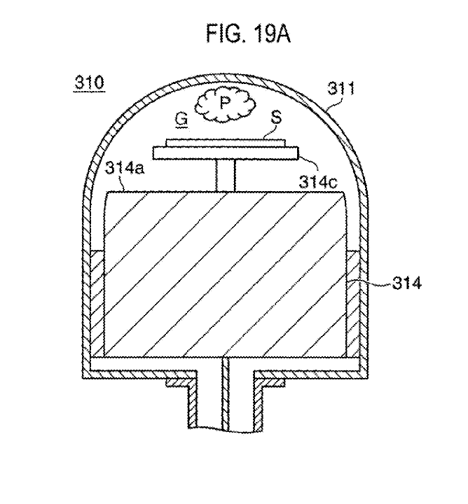

In addition, a dielectric window 315 is disposed between the inner wall surface of the processing chamber 311 and a lateral surface of the stage 314 (for example, see FIG. 18A). Further, the waveguide 312 is connected to a central portion of the lower end in FIG. 17 of the processing chamber 311 (for example, see FIG. 18B). That is, the waveguide 312 is disposed on the central axis C of the processing chamber 311.

In the plasma processing apparatus 310, the microwave propagated by the waveguide 312 is introduced into the plasma generation space G through the dielectric window 315. Here, since the dielectric window 315 faces the plasma generation space G along the circumference of the plasma generation space G, i.e., faces the plasma generation space G symmetrically with respect to the central axis C, the microwave is introduced symmetrically with respect to the center of the plasma generation space G.

Further, since the plasma generation space G is defined by the hemispherical inner wall surface 311a of the processing chamber 311 and the substrate mounting surface 314a of the stage 314, the plasma generation space G is shaped in a hemisphere symmetric with respect to the central axis C. With this configuration, as a radius of the plasma generation space G is appropriately set, an electromagnetic wave of a specific mode can be excited. As a result, a strong electric field region can be formed in an arbitrary region in the space, e.g., an upper part of the center of the plasma generation space G. In the strong electric field region, since a large amount of energy migrating from the microwave to electrons in plasma causes electron temperature to be high, and thus, electrons having sufficient energy repeatedly collide with atoms or molecules in the processing gas, thereby locally generating high density plasma. That is, since the plasma is actively generated in the strong electric field region more than the other regions, high density plasma P is generated in the strong electric field region. In other words, in this embodiment, the plasma P is generated in an arbitrary region from the processing gas only by the introduction of the microwave without using a magnetic field or the like.

In addition, a part of the plasma P generated in the plasma generation space G reaches the substrate S mounted on the substrate mounting surface 314a of the stage 314 facing the plasma generation space G, and plasma processing is performed on the substrate S. For example, in the plasma processing apparatus 310, a mixture gas containing hydrogen gas, a carbon-containing gas such as methane gas, propane gas or acetylene gas, and an impurity-containing gas such as phosphine gas or diborane gas may be used as the processing gas, and by maintaining the plasma generation space G or the interior of the processing chamber 311 at a pressure of 10 to 200 Torr and by heating the substrate S at 700 to 1200 degrees C. using the stage 314, a diamond film is grown on the substrate S by radicals in the plasma P generated from the processing gas.

According to the plasma processing apparatus 310 of FIG. 17, since the upper end side of the processing chamber 311 into which the microwave is introduced is shaped in a hemisphere symmetric with respect to the central axis C and the plasma generation space G in the processing chamber 311 is also shaped in a hemisphere symmetric with respect to the central axis C, as their radii are appropriately set, an electromagnetic wave of a specific mode can be excited, and a strong electric field region can be generated in an arbitrary region according to the specific mode. Therefore, the plasma P can be generated in a region spaced apart from the dielectric window 315. As a result, the dielectric window 315 can be prevented from being damaged by heat of the plasma P. In addition, since the plasma P is generated in a region spaced apart from the dielectric window 315, an electric potential gradient in a sheath generated in the vicinity of the surface of the dielectric window 315 can be weakened, thereby making it possible to weaken sputtering of positive ions by the sheath toward the dielectric window 315.

In addition, since the plasma generation space G is shaped in a hemisphere symmetric with respect to the central axis C, the plasma P to be generated is also distributed symmetrically with respect to the central axis C. Accordingly, it is possible to prevent the generation of abnormal discharge caused by plasma maldistribution.

Further, in the plasma processing apparatus 310, since the microwave is introduced symmetrically with respect to the central axis C of the processing chamber 311, it is easy to set a radius necessary for exciting the electromagnetic wave of the specific mode and to predict the position in which the strong electric field region is generated, and therefore, the generation region of the plasma P can be easily controlled.

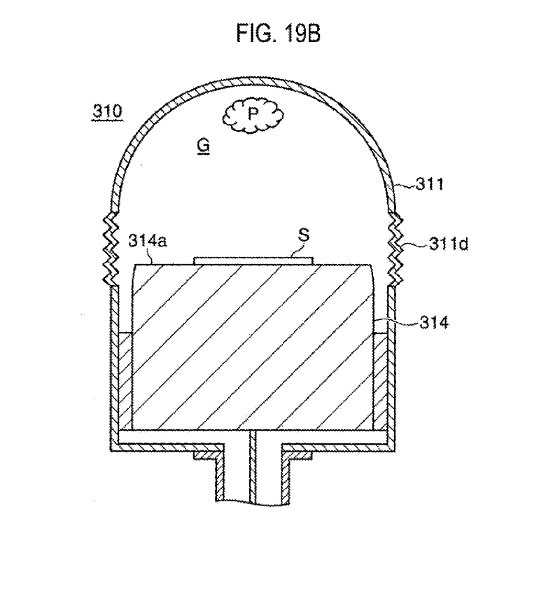

Further, in the plasma processing apparatus 310, a part of the substrate mounting surface 314a of the stage 314 in the processing chamber 311 may be configured to have a lift table 314c, which is movable in the up and down direction, as shown in FIG. 19A. With this configuration, the distance between the plasma P and the substrate S can be controlled.

Also, as shown in FIG. 19B, a part of a sidewall of the processing chamber 311 may be configured to have a bellows 311d. In this case, the distance between the hemispherical upper end side of the processing chamber 311 and the substrate S mounted on the stage 314 may be changed by extending the bellows 311d. Here, since the strong electric field region is generated in the hemispherical upper end side of the processing chamber 311, the distance between the plasma P and the substrate S can be controlled resultingly.

Therefore, in the plasma processing apparatus of FIG. 19A or 19B, as the distance between the plasma P and the substrate S is controlled, a film forming rate or a film thickness distribution on the substrate S can be controlled when a film is formed using the plasma P, and an etching rate or an etching rate distribution on the substrate S can be controlled when etching is performed using the plasma P.

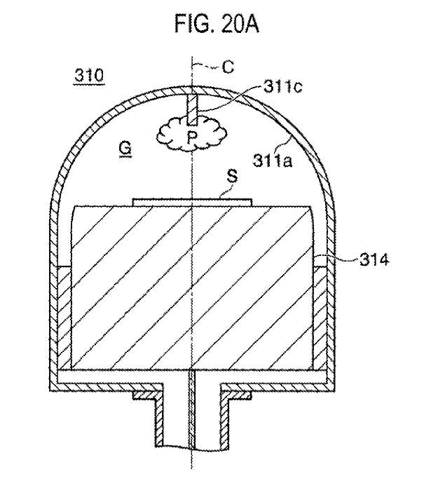

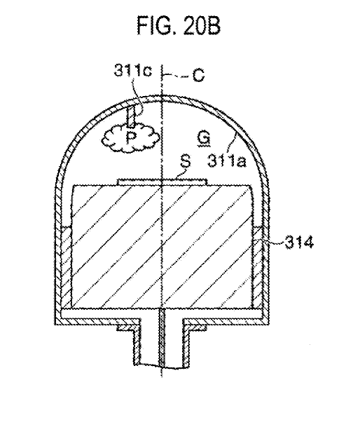

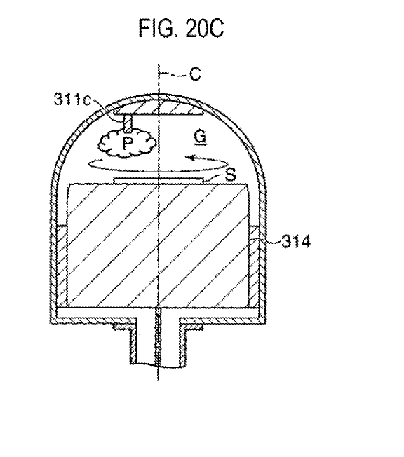

In addition, as shown in FIG. 20A, a protrusion member (stub) 311c may be installed on the hemispherical inner wall surface 311a of the processing chamber 311 along the central axis C to face the stage 314. In general, plasma is locally generated in the vicinity of a leading end of a protrusion. Therefore, a generation region of the plasma P can be finely controlled with respect to the vertical direction in the plasma generating space G by adjusting the length of the stub 311c. In order to locally generate the plasma P in the vicinity of the leading end of the stub 311c, it is necessary for at least the leading end of the stub 311c to be present in the plasma generating space G. The material of the stub 311c is not specially limited, but a conductor, e.g., metal, is preferred.

In addition, the stub 311c need not be disposed along the central axis C and may be offset from the central axis C as shown in FIG. 20B. Even if the stub 311c is offset from the central axis C, as long as the leading end of the stub 311c is present in the plasma generating space G, the plasma P can be locally generated in the vicinity of the leading end. Therefore, the generation location of the plasma P can be controlled by adjusting the location in which the stub 311c is disposed.

Further, the stub 311c may be configured to be movable in the plasma generating space G. For example, as shown in FIG. 20C, the stub 311c may be configured to be movable circularly about the central axis C while facing the stage 314. Even in such a case, since the plasma P is locally generated in the vicinity of the leading end of the stub 311c, the plasma P can be moved by moving the stub 311c. With this configuration, the exposure time to the plasma P at every point of the substrate S can be controlled, and thus, the plasma processing can be uniformly performed on the substrate S.

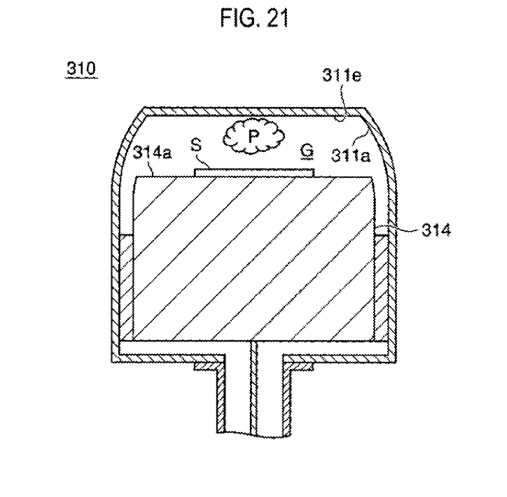

Further, as shown in FIG. 21, the hemispherical inner wall surface 311a may be provided with a flat plate-shaped facing surface 311e by truncating a portion of the upper end side of the processing chamber 311 that faces the stage 314. Even in this case, since a curved portion is remained in a part of the hemispherical inner wall surface 311a, an electromagnetic wave of a specific mode can be excited by appropriately setting a radius of the curved portion, and the plasma P can be generated in an arbitrary region according to the specific mode. Meanwhile, since the facing surface 311e becomes closer to the substrate mounting surface 314a of the stage 314 than the top portion of the hemispherical inner wall surface 311a in FIG. 17, the plasma P to be generated can be close to the substrate S mounted on the substrate mounting surface 314a, and therefore, efficiency of the plasma processing performed on the substrate S can be improved.

Next, a plasma processing apparatus according to a fifth embodiment of the present disclosure will be described.

Since this embodiment is basically equal to the above-described fourth embodiment in configuration and function, descriptions of the overlapped configurations and functions will be omitted, and different configurations and functions will be described below.

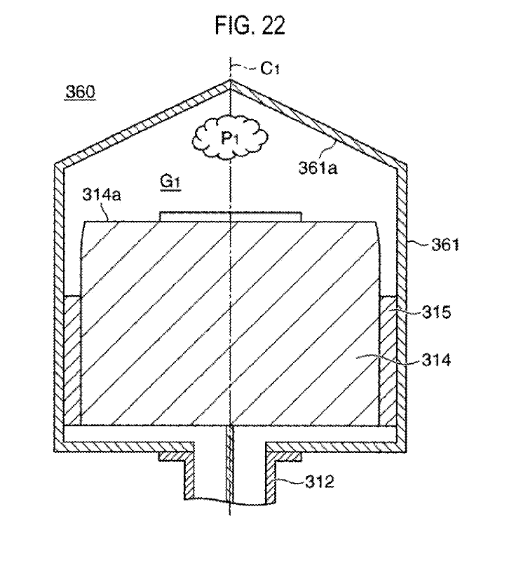

FIG. 22 is a sectional view schematically showing a configuration of the plasma processing apparatus according to this embodiment.

In FIG. 22, a plasma processing apparatus 360 includes a processing chamber (plasma generation vessel) 361 configured to perform plasma processing on a substrate S, and a waveguide 312.

The processing chamber 361 has a central axis C₁, has a shape symmetrical with respect to the central axis C₁, and has an upper end side in FIG. 22 formed in the shape of a cone and a lower end side in the figure formed in the shape of a cylinder. A stage 314 is disposed coaxially with the processing chamber 361 in the processing chamber 361. A conical inner wall surface 361a in the upper end side of the processing chamber 361 and the substrate mounting surface 314a of the stage 314 define a plasma generation space G₁.

Further, the waveguide 312 is connected to a central portion of the lower end in FIG. 22 of the processing chamber 361. That is, the waveguide 312 is disposed on the central axis C₁ of the processing chamber 361. In the plasma processing apparatus 360, a microwave is introduced through the dielectric window 315 symmetrically with respect to the center of the plasma generation space G₁.

Further, since the plasma generation space G₁ is defined by the conical inner wall surface 361a of the processing chamber 361 and the substrate mounting surface 314a of the stage 314, the plasma generation space G₁ is shaped in a cone symmetric with respect to the central axis C₁. As a position of a conical surface of the cone is appropriately set, an electromagnetic wave of a specific mode can be excited, a local strong electric field region is generated in an arbitrary region according to the specific mode, e.g., an upper portion of the plasma generation space G₁, and plasma P₁ is generated. In addition, a part of the plasma P₁ generated in the plasma generation space G₁ reaches the substrate S mounted on the substrate mounting surface 314a facing the plasma generation space G₁, and plasma processing is performed on the substrate S.

According to the plasma processing apparatus 360 of FIG. 22, since the upper end side of the processing chamber 361 into which the microwave is introduced is shaped in a cone symmetric with respect to the central axis C₁ and the plasma generation space G₁ in the processing chamber 361 is also shaped in a cone symmetric with respect to the central axis C₁, as a conical surface position of the cones is appropriately set, an electromagnetic wave of a specific mode can be excited and a strong electric field region can be generated in an arbitrary region according to the specific mode. Therefore, the plasma P₁ can be generated in a region spaced apart from the dielectric window 315. In addition, an electric potential gradient in a sheath generated in the vicinity of the surface of the dielectric window 315 can be weakened, thereby making it possible to weaken sputtering of positive ions by the sheath toward the dielectric window 315.

In addition, since the plasma generation space G₁ is shaped in a cone symmetric with respect to the central axis C₁, the plasma P₁ to be generated is also distributed symmetrically with respect to the central axis C₁. Accordingly, it is possible to prevent the generation of abnormal discharge caused by plasma maldistribution.

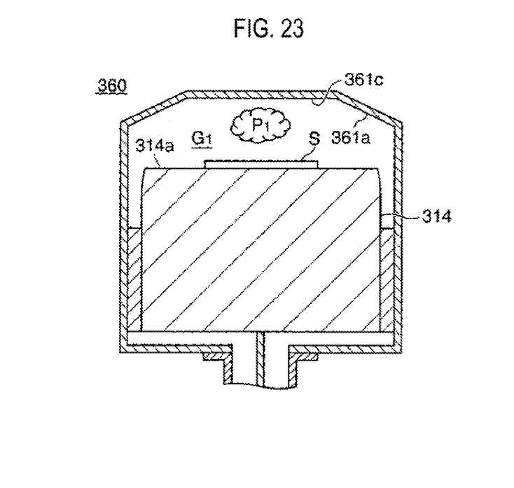

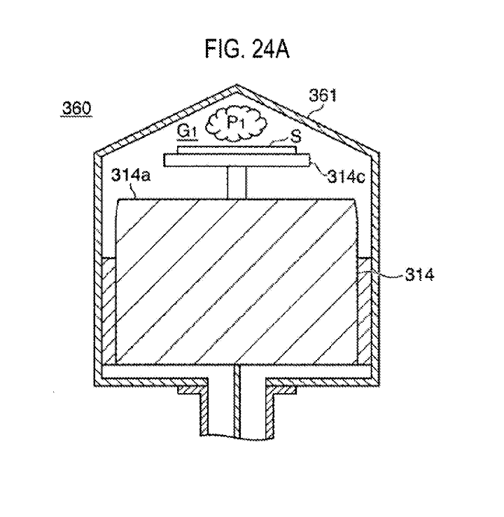

Further, as shown in FIG. 23, the conical inner wall surface 361a may be provided with a flat plate-shaped facing surface 361c by truncating a portion of the upper end side of the processing chamber 361 that faces the stage 314. Even in this case, since an inclined portion is remained a part of in the conical inner wall surface 361a, an electromagnetic wave of a specific mode can be excited by appropriately setting a position of the inclined portion, and the plasma P₁ can be generated in an arbitrary region according to the mode. Meanwhile, since the facing surface 361c becomes closer to the substrate mounting surface 314a of the stage 314 than the top portion of the conical inner wall surface 361a in FIG. 17, the plasma P₁ to be generated can be close to the substrate S mounted on the substrate mounting surface 314a, and therefore, efficiency of the plasma processing performed on the substrate S can be improved.

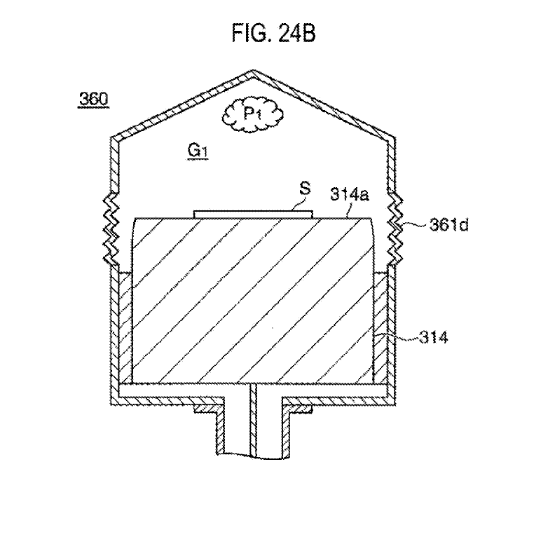

Further, in the plasma processing apparatus 360, a part of the substrate mounting surface 314a of the stage 314 in the processing chamber 361 may be configured to have a lift table 314c, which is movable in the up and down direction, as shown in FIG. 24A. With this configuration, the distance between the plasma P₁ and the substrate S can be controlled. Also, as shown in FIG. 24B, a part of a sidewall of the processing chamber 361 may be configured to have a bellows 361d. Even in this case, the distance between the plasma P₁ and the substrate S can be controlled by stretching the bellows 361d.

Also, in the same way as the plasma processing apparatus 310 shown in FIG. 20A, a stub facing the stage 314 may be installed on the conical inner wall surface 361a of the processing chamber 361 of the plasma processing apparatus 360 along the central axis C₁.

Hereinabove, while the present disclosure has been described using the above-described respective embodiments, the present disclosure is not limited to the above-described respective embodiments.

In the above-described fourth or fifth embodiment, it is thought that a main factor of the generation of the strong electric field region in an arbitrary region according to a mode in the plasma generation space G or G₁ of the plasma processing apparatus 310 or 360 is that the upper end side of the processing chamber 311 having the hemispherical inner wall surface 311a or the upper end side of the processing chamber 361 having the conical inner wall surface 361a is shaped to be symmetric with respect to the central axis C or C₁ and a mode of the excited electromagnetic wave can be specified by adjusting the shape thereof. Therefore, if only the plasma generating space G has an appropriate shape, regardless of what type of the microwave is introduced into the plasma generating space G, for example, even if the microwave is not introduced symmetrically with respect to the center of the plasma generating space G, an approximately local strong electric field region can be generated in an arbitrary region of the plasma generation space G.

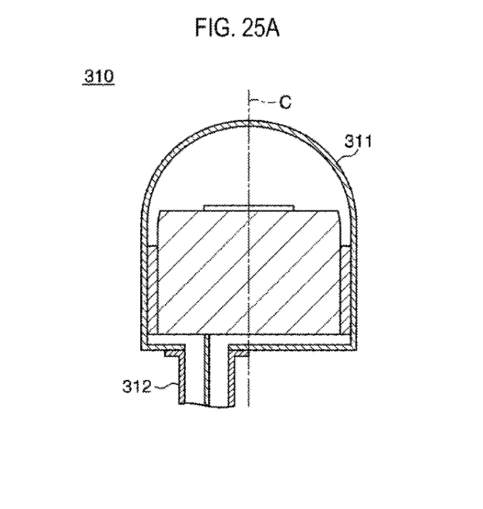

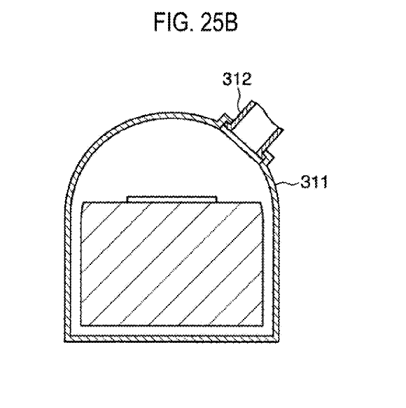

For the above-described reasons, there is a degree of freedom in disposing the waveguide 312, and contrary to the plasma processing apparatus 310 of FIG. 17, the waveguide 312 need not be disposed on the central axis C of the processing chamber 311. As shown in FIG. 25A, one waveguide 312 may be disposed offset from the central axis C of the processing chamber 311. In addition, the microwave need not be introduced through the dielectric window 315 into the plasma generating space G. For example, as shown in FIG. 25B, the waveguide 312 may be installed directly at the upper end side of the processing chamber 311.

### Example

Next, examples of the present disclosure will be described.

First, in order to evaluate influences of the up and down movement of the lift table 314c in the stage 314 on a generation pattern of the local strong electric field region, 2-dimensional models of Examples 14 to 16 were prepared based on the plasma processing apparatus 310 of FIG. 19A. For example, the height of the lift table 314c from the substrate mounting surface 314a was set to 0 cm in Example 14, the height of the lift table 314c from the substrate mounting surface 314a was set to 2 cm in Example 15, and the height of the lift table 314c from the substrate mounting surface 314a was set to 3 cm in Example 16.

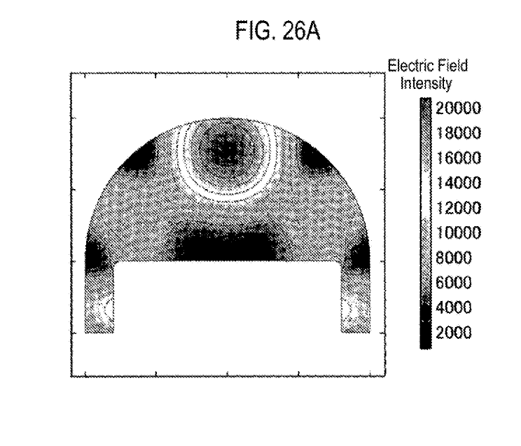

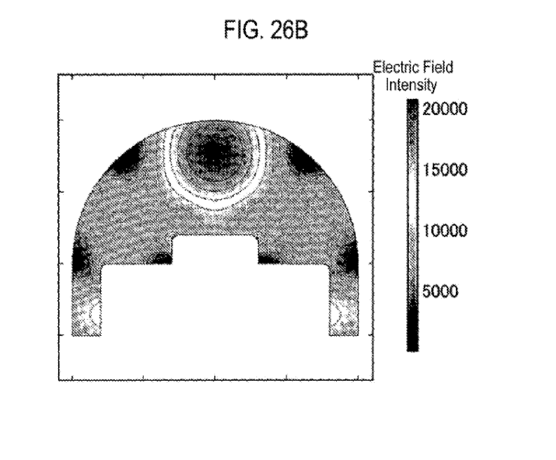

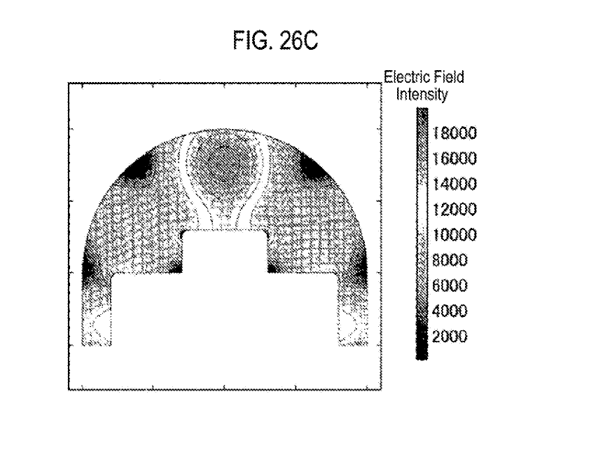

Successively, on the assumption that low density plasma having a uniform distribution of nₑ=10¹⁶ m⁻³, which meets ω>ωₚₑ, has already existed in the plasma generating space G (wherein ω designates a microwave (angular) frequency, ωₚₑ designates an electron plasma (angular) frequency, and nₑ designates an electron density) and momentum transfer collision frequency νₘ is equal to ω, electric field intensity distributions were calculated in Examples 14 and 16 using an electronic computation module produced by COMSOL Inc., and the results thereof are shown in FIGS. 26A to 26C. Here, FIG. 26A shows an electric field intensity distribution in Example 14, FIG. 26B shows an electric field intensity distribution in Example 15, and FIG. 26C shows an electric field intensity distribution in Example 16.

As shown in FIGS. 26A to 26C, it could be seen that if the plasma generating space G is shaped in a hemisphere symmetric with respect to the central axis C, a local strong electric field region can be generated even though the height of the lift table 314c is changed. Accordingly, it was assumed that the shape of the plasma generating space G is a main factor in the generation of the local strong electric field region. It could also be seen that although the lift table 314c is moved up and down, a position of the local strong electric field region is hardly changed. Accordingly, it could be seen that a desired film forming rate or etching rate can be easily realized only by moving the lift table 314c up and down.

Then, in order to evaluate influences of a difference in length of the stub 311c on a generation pattern of the local strong electric field region, 2-dimensional models of Examples 17 to 19 were prepared based on the plasma processing apparatus 310 of FIG. 20A. For example, the length of the stub 311c was set to 1 cm in Example 17, the length of the stub 311c was set to 2 cm in Example 18, and the length of the stub 311c was set to 3 cm in Example 19.

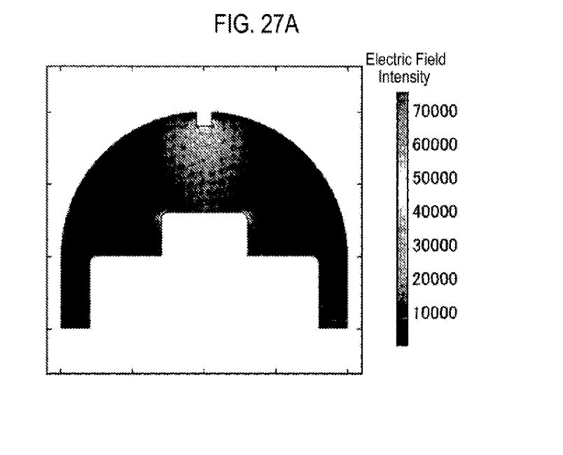

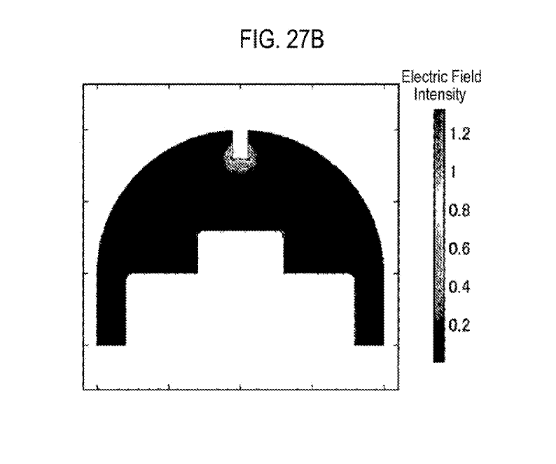

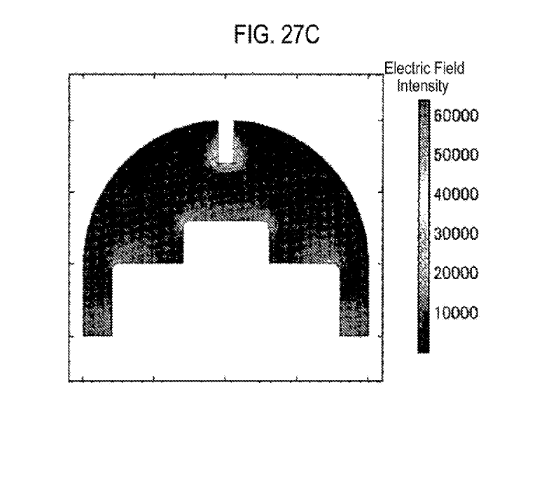

In succession, under the same conditions as Examples 14 to 16, electric field intensity distributions were calculated in Examples 17 to 19 using the same electronic computation module produced by COMSOL Inc., and the results thereof are shown in FIGS. 27A to 27C. Here, FIG. 27A shows an electric field intensity distribution in Example 17, FIG. 27B shows an electric field intensity distribution in Example 18, and FIG. 27C shows an electric field intensity distribution in Example 19.

As shown in FIGS. 27A to 27C, it could be seen that although the length the stub 311c is changed, the strong electric field region is locally generated corresponding to the position of the leading end of the stub 311c. Accordingly, it could be seen that a generation region of plasma P can be controlled by changing the length of the stub 311c.

Next, in order to evaluate influences of the provision of the facing surface 311e and a difference in distance between the facing surface 311e and the substrate mounting surface 314a on a generation pattern of the local strong electric field region, 2-dimensional models of Examples 20 to 22 were prepared based on the plasma processing apparatus 310 of FIG. 21. For example, the distance between the facing surface 311e and the substrate mounting surface 314a was set to 7 cm in Example 20, the distance between the facing surface 311e and the substrate mounting surface 314a was set to 6 cm in Example 21, and the distance between the facing surface 311e and the substrate mounting surface 314a was set to 5 cm in Example 22.

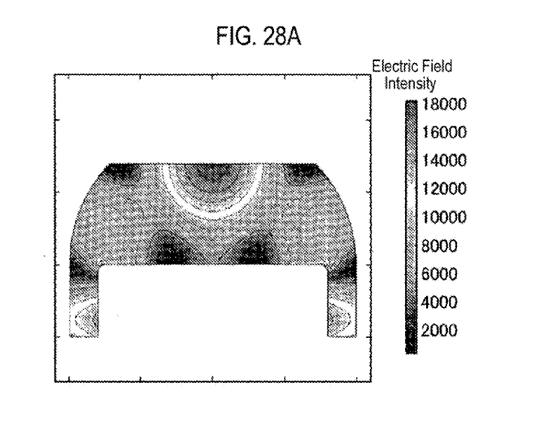

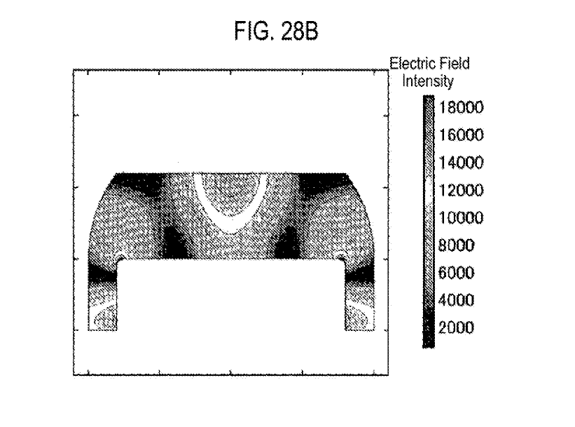

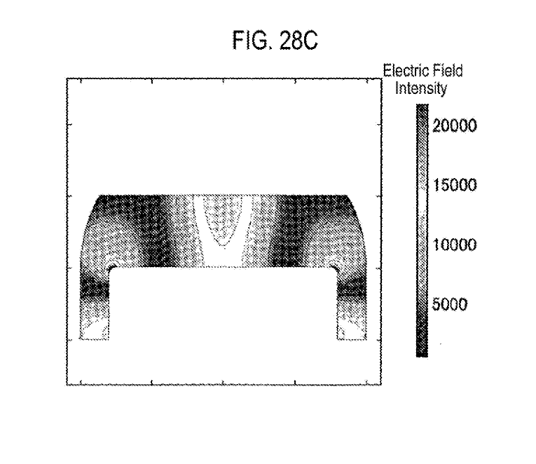

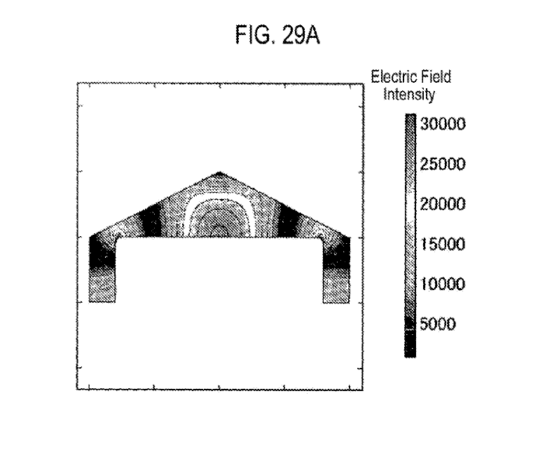

In succession, under the same conditions as Examples 14 to 16, electric field intensity distributions were calculated in Examples 20 to 22 using the same electronic computation module produced by COMSOL Inc., and the results thereof are shown in FIGS. 28A to 28C. Here, FIG. 28A shows an electric field intensity distribution in Example 20, FIG. 28B shows an electric field intensity distribution in Example 21, and FIG. 28C shows an electric field intensity distribution in Example 22.

As shown in FIGS. 28A to 28C, it could be seen that the strong electric field region is locally generated even though the facing surface 311e is provided. Accordingly, it could be seen that if the curved portion is remained in a part of the hemispherical inner wall surface 311a, although the upper end side of the processing chamber 311 is not shaped in a complete hemisphere, the plasma P can be generated in the plasma generating space G. In addition, it could be seen that even though the distance between the facing surface 311e and the substrate mounting surface 314a is changed, the strong electric field region is generated in the vicinity of the facing surface 311e. Accordingly, it could also be seen that a distance between the plasma P and the substrate S can be controlled by changing the distance between the facing surface 311e and the substrate mounting surface 314a.

Next, in order to evaluate influences of a difference in distance between the apex of the conical inner wall surface 361a and the stage 314 on a generation pattern of the local strong electric field region, 2-dimensional models of Examples 23 to 25 were prepared based on the plasma processing apparatus 360 of FIG. 22. The distance between the apex of the conical inner wall surface 361a and the stage 314 was set to 5 cm in Example 23, the distance between the apex of the conical inner wall surface 361a and the stage 314 was set to 7.5 cm in Example 24, and the distance between the apex of the conical inner wall surface 361a and the stage 314 was set to 10 cm in Example 25.

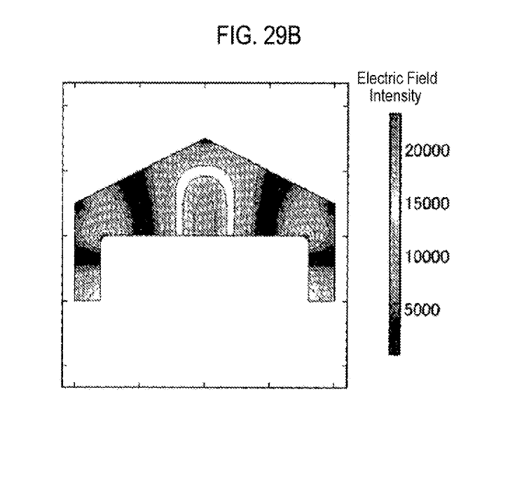

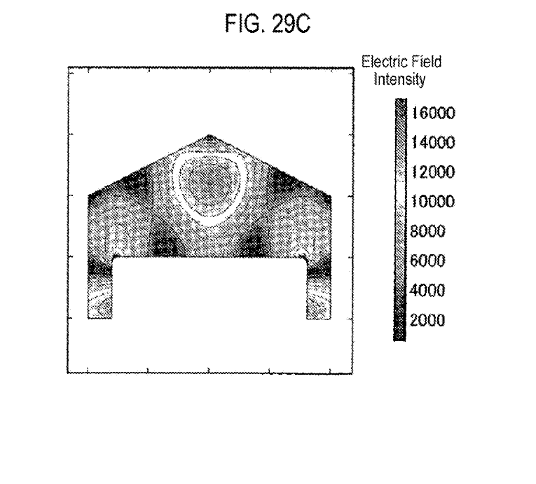

In succession, under the same conditions as Examples 14 to 16, electric field intensity distributions were calculated in Examples 23 to 25 using the same electronic computation module produced by COMSOL Inc., and the results thereof are shown in FIGS. 29A to 29C. Here, FIG. 29A shows an electric field intensity distribution in Example 23, FIG. 29B shows an electric field intensity distribution in Example 24, and FIG. 29C shows an electric field intensity distribution in Example 25.

As shown in FIGS. 29A to 29C, it could be seen that, if the plasma generating space G₁ is shaped in a cone symmetric with respect to the central axis C₁, the local strong electric field region can be generated even though the distance between the apex of the conical inner wall surface 361a and the stage 314 is changed. Accordingly, it was also assumed that the shape of the plasma generation space G₁ is a main factor in the generation of the local strong electric field region. In addition, it could be seen that if the distance between the apex of the conical inner wall surface 361a and the stage 314 is changed, a region in which the local strong electric field region is generated is also changed. Accordingly, it could also be seen that the distance between the plasma P₁ and the substrate S can be controlled by changing the distance between the apex of the conical inner wall surface 361a and the stage 314.

Next, in order to evaluate influences of the provision of the facing surface 361c and a difference in distance between the facing surface 361c and the substrate mounting surface 314a on a generation pattern of the local strong electric field region, 2-dimensional models of Examples 26 to 28 were prepared based on the plasma processing apparatus 360 of FIG. 23. For example, the distance between the facing surface 361c and the substrate mounting surface 314a was set to 7 cm in Example 26, the distance between the facing surface 361c and the substrate mounting surface 314a was set to 6 cm in Example 27, and the distance between the facing surface 361c and the substrate mounting surface 314a was set to 5 cm in Example 28.

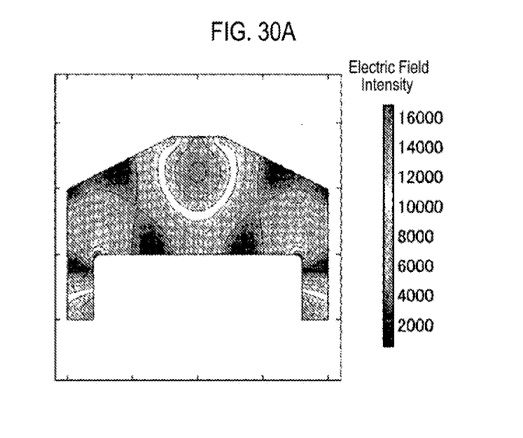

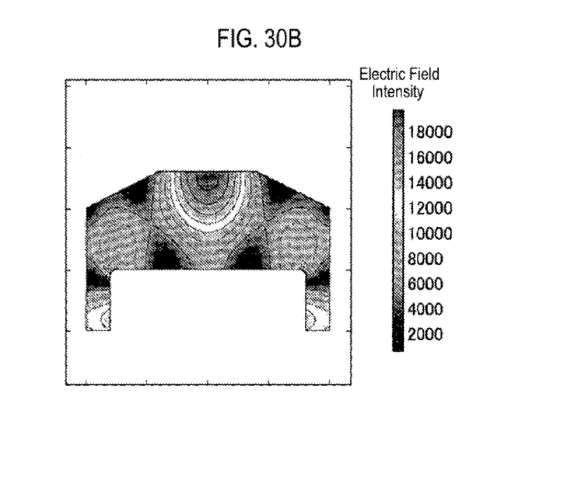

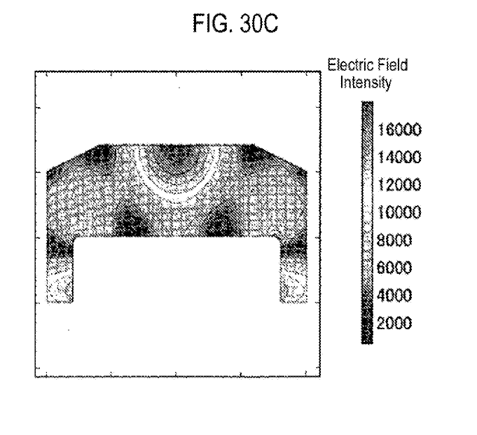

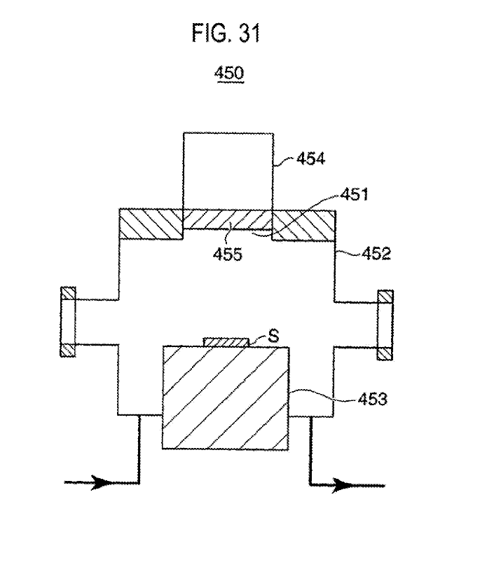

In succession, under the same conditions as Examples 14 to 16, electric field intensity distributions were calculated in Examples 26 to 28 using the same electronic computation module produced by COMSOL Inc., and the results thereof are shown in FIGS. 30A to 30C. Here, FIG. 30A shows an electric field intensity distribution in Example 26, FIG. 30B shows an electric field intensity distribution in Example 27, and FIG. 30C shows an electric field intensity distribution in Example 28.

As shown in FIGS. 30A to 30C, it could be seen that the strong electric field region is locally generated even though the facing surface 361c is provided. Accordingly, it could be seen that if the inclined portion is remained in a part of the conical inner wall surface 361a, although the upper end side of the processing chamber 361 is not completely a cone-shape, the plasma P₁ can be generated in the plasma generating space G₁. In addition, it could be seen that even though the distance between the facing surface 361c and the substrate mounting surface 314a is changed, the strong electric field region is generated in the vicinity of the facing surface 361c. Accordingly, it could also be seen that a distance between the plasma P₁ and the substrate S can be controlled by changing the distance between the facing surface 361c and the substrate mounting surface 314a.

According to the present disclosure, since the plasma generation vessel into which a microwave is introduced is sphere-shaped, as a radius of the plasma generation vessel, which is a boundary condition of an electromagnetic wave present in the plasma generation vessel, is appropriately set, it is possible to excite an electromagnetic wave of a specific mode. As a result, a strong electric field region may be generated in an arbitrary region according to the mode. The strong electric field region allows plasma to be generated from a processing gas. Therefore, as the strong electric field region is generated in a desired region spaced apart from a dielectric window and positioned around a substrate that is an object to be processed, the plasma can be generated in a region spaced apart from the dielectric window. Accordingly, it is possible to prevent the dielectric window from being damaged by the plasma and also to generate the plasma in the desired region around the substrate.

In addition, according to the present disclosure, since the plasma generation vessel into which a microwave is introduced has a hemispherical curved space portion provided between a curved surface of a hemispherical body and an inner curved surface of a hollow hemispherical body facing the hemispherical body with a predetermined interval therebetween, the hollow hemispherical body having a diameter larger than that of the hemispherical body and being disposed concentrically with the hemispherical body, as inner and outer diameters of the hemispherical curved space portion, which are boundary conditions of an electromagnetic wave, are appropriately set, it is possible to excite an electromagnetic wave of a specific mode. As a result, a strong electric field region may be generated in an arbitrary region according to the mode. The strong electric field region allows plasma to be generated from a processing gas. Therefore, as the strong electric field region is generated in a desired region spaced apart from a dielectric window and positioned around a substrate that is an object to be processed, the plasma can be generated in a region spaced apart from the dielectric window. Accordingly, it is possible to prevent the dielectric window from being damaged by the plasma and thus to further generate the plasma in the desired region around the substrate.

In addition, according to the present disclosure, since the plasma generation vessel into which a microwave is introduced has a shape symmetric with respect to the central axis, as an inner diameter of a shape, e.g., a hemisphere, of the plasma generation vessel, which is a boundary condition of an electromagnetic wave present in the plasma generation vessel, is appropriately set, it is possible to excite an electromagnetic wave of a specific mode. As a result, a strong electric field region may be generated in an arbitrary region according to the mode. The strong electric field region allows plasma to be generated from a processing gas. Therefore, as the strong electric field region is generated in a desired region spaced apart from a dielectric window and positioned around a substrate that is an object to be processed, the plasma can be generated in a region spaced apart from the dielectric window. Accordingly, it is possible to prevent the dielectric window from being damaged by the plasma and also to generate the plasma in the desired region around the substrate.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma generation device, comprising:
a waveguide configured to propagate a microwave;
a plasma generation vessel connected to the waveguide; and
a dielectric window interposed between the waveguide and the plasma generation vessel to introduce the microwave propagated by the waveguide into the plasma generation vessel,
wherein the plasma generation vessel is sphere-shaped and is disposed adjacent to a processing vessel configured to accommodate a substrate, and an interior of the plasma generation vessel is in communication with an interior of the processing vessel.

2. The plasma generation device of claim 1, wherein the plasma generation vessel is in communication with the processing vessel through an opening formed in a part of a spherical curved surface of the plasma generation vessel.

3. The plasma generation device of claim 1, wherein the waveguide is disposed symmetrically with respect to a central axis of the plasma generation vessel.

4. The plasma generation device of claim 1, wherein the dielectric window is disposed along a circumference of the plasma generation vessel.

5. A plasma processing apparatus, comprising:
a processing vessel configured to accommodate a substrate therein; and
a plasma generation device disposed adjacent to the processing vessel,
wherein the plasma generation device includes a waveguide configured to propagate a microwave, a plasma generation vessel connected to the waveguide, and a dielectric window interposed between the waveguide and the plasma generation vessel to introduce the microwave propagated by the waveguide into the plasma generation vessel,
wherein the plasma generation vessel is sphere-shaped and an interior of the plasma generation vessel is in communication with an interior of the processing vessel.

6. The plasma processing apparatus of claim 5, wherein the plasma generation vessel is in communication with the processing vessel through an opening formed in a part of a spherical curved surface of the plasma generation vessel.

7. The plasma processing apparatus of claim 5, wherein the waveguide is disposed symmetrically with respect to a central axis of the plasma generation vessel.

8. The plasma processing apparatus of claim 5, wherein the dielectric window is disposed along a circumference of the plasma generation vessel.
